(19) United States
(12) Patent Application Publication
(10) Pub. No.: US 2024/0072055 A1
(43) Pub. Date: Feb. 29, 2024

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Shahaji B. MORE, Hsinchu (TW); Cheng-Wei Chang, Taipei (TW)

(21) Appl. No.: 17/897,151

(22) Filed: Aug. 27, 2022

(51) Int. Cl. H01L 27/092; H01L 21/8238; H01L 29/08; H01L 29/40; H01L 29/417; H01L 29/66; H01L 29/78

(52) U.S. Cl. CPC H01L 27/0924; H01L 21/823814; H01L 21/823821; H01L 21/823871; H01L 21/823878; H01L 29/0847; H01L 29/401; H01L 29/41775; H01L 29/41791; H01L 29/66545; H01L 29/66795; H01L 29/7851; H01L 29/41733; H01L 29/42392

(57) ABSTRACT

A semiconductor device structure, along with methods of forming such, are described. The semiconductor device structure includes a substrate comprising an NMOS region and a PMOS region abutting the NMOS region, a first shallow trench isolation (STI) disposed across the PMOS region and the NMOS region, the first STI has a first bottom being slanted from the NMOS region towards the PMOS region. The semiconductor device structure also includes a first fin disposed in the PMOS region, a first source/drain epitaxial feature disposed over the first fin, a second fin disposed in the NMOS region, a second source/drain epitaxial feature disposed over the second fin, a first dielectric feature disposed between the first source/drain epitaxial feature and the second source/drain epitaxial feature, the first dielectric feature having a portion embedded in the first STI. The semiconductor device structure further includes a conductive feature disposed over the first and second source/drain epitaxial features and the first dielectric feature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

As the geometry size decreases, semiconductor devices, such as fin field-effect transistors (FinFETs), may be negatively impacted by the short channel effect and increased source/drain electron tunneling. Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are cross-sectional side views of various stages of manufacturing a semiconductor device structure, in accordance with some embodiments.

FIG. 1C-1 illustrates an enlarged view of a portion of the semiconductor device structure, in accordance with some embodiments.

FIGS. 2A-7A are cross-sectional side views of various stages of manufacturing the semiconductor device structure of FIG. 1F taken along line A-A, in accordance with some embodiments.

FIGS. 2B-7B are cross-sectional side views of various stages of manufacturing the semiconductor device structure of FIG. 1F, in accordance with some embodiments.

FIGS. 8 and 9 are cross-sectional side views of one of various stages of manufacturing the semiconductor device structure, in accordance with some embodiments.

FIGS. 10A-11A and 10B-11B are cross-sectional side views of one of various stages of manufacturing the semiconductor device structures of FIG. 9, in accordance with some embodiments.

FIGS. 12-14 are cross-sectional side views of a stage of manufacturing the semiconductor device structure, in accordance with some embodiments.

FIGS. 15-1 and 15-2 are cross-sectional side views of a stage of manufacturing the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

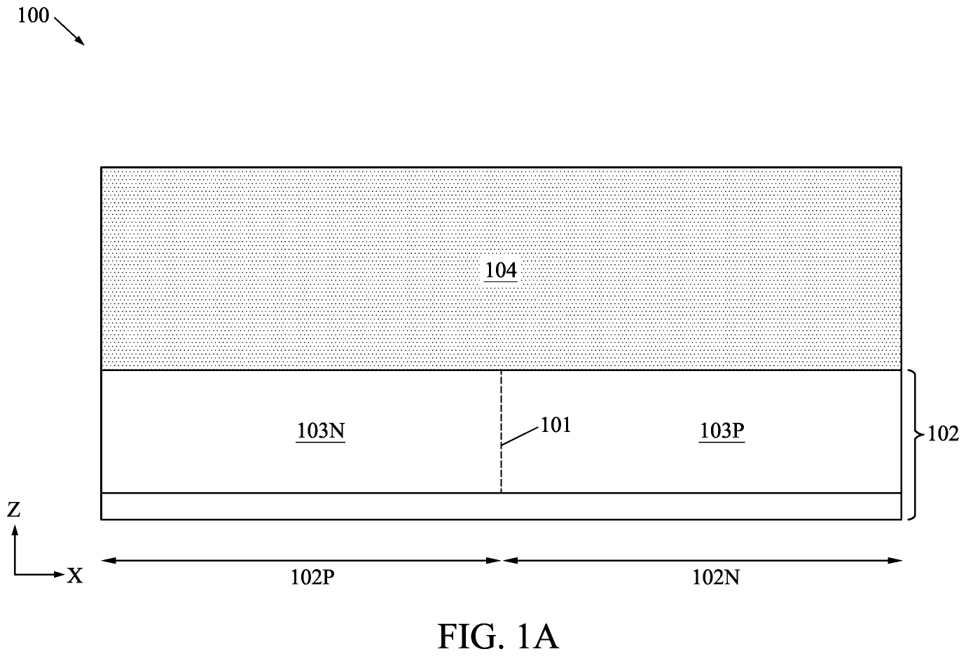

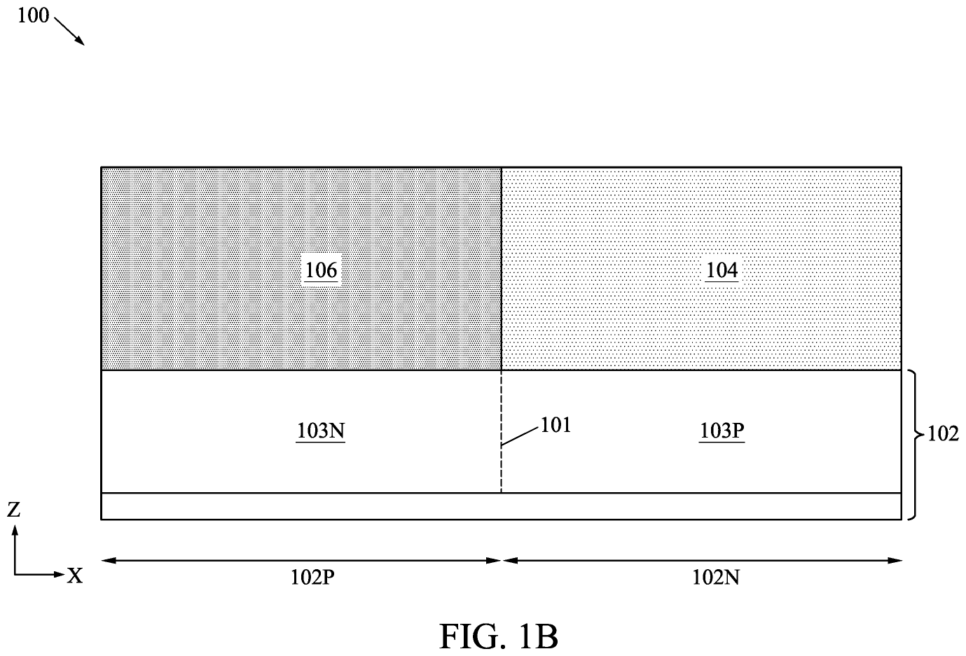

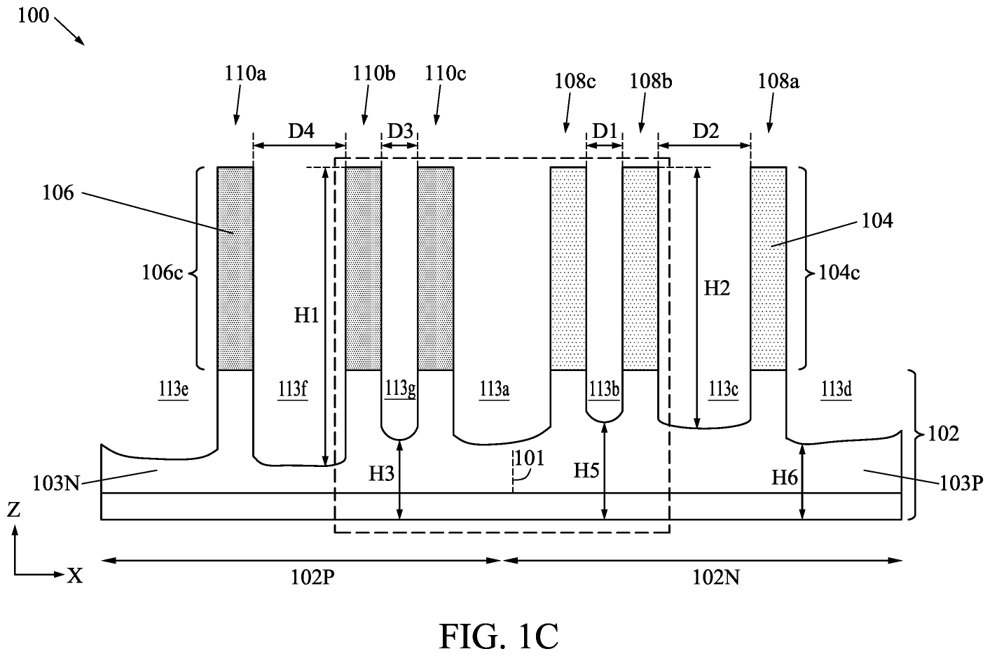

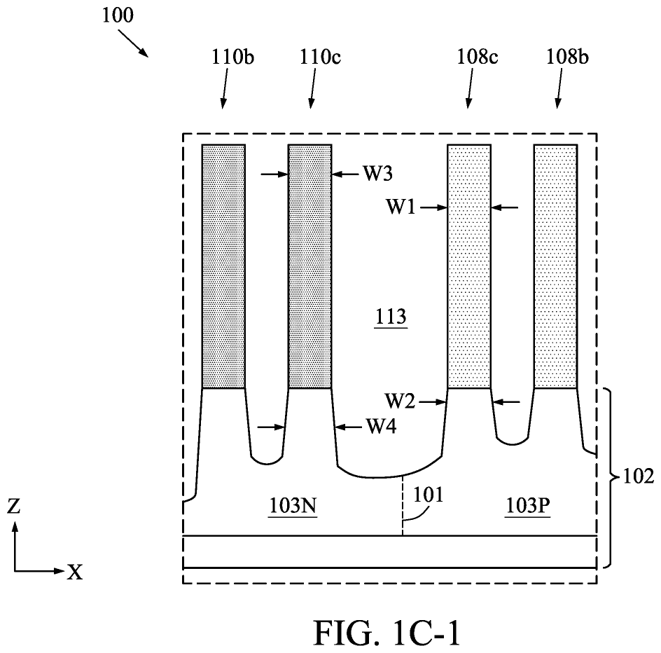

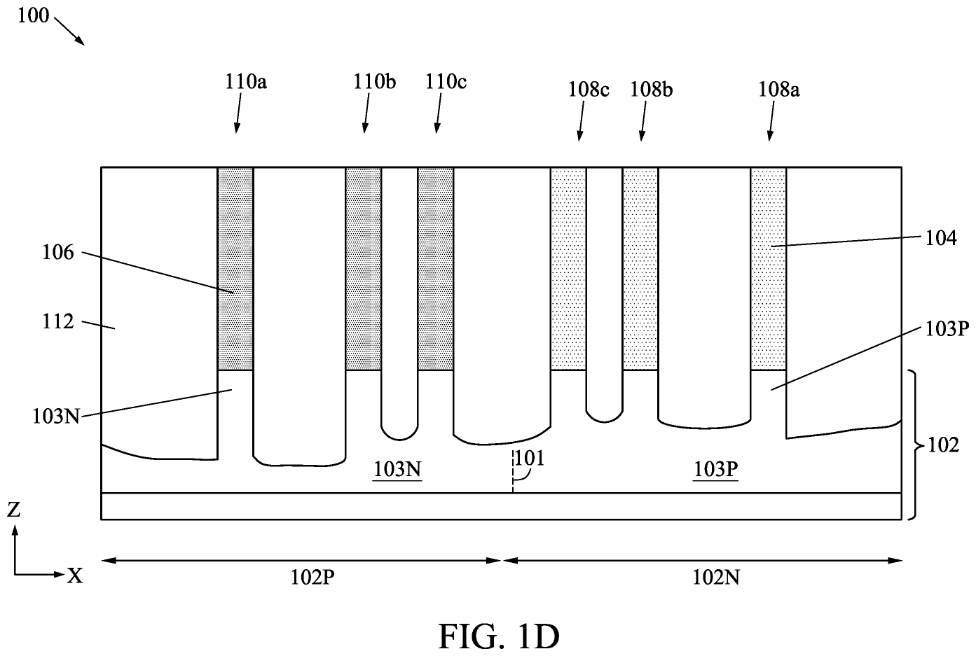

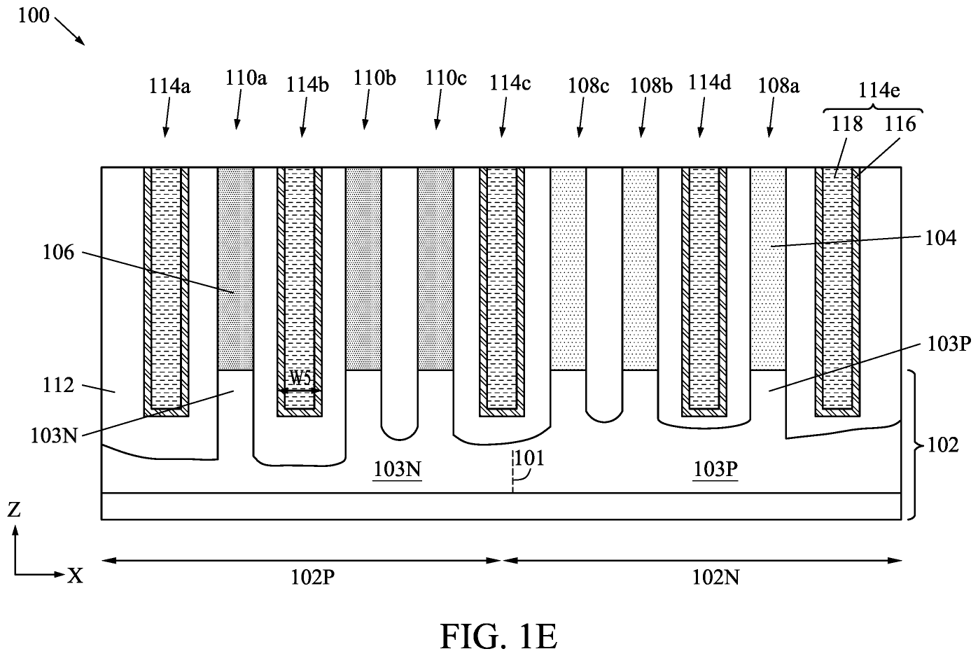

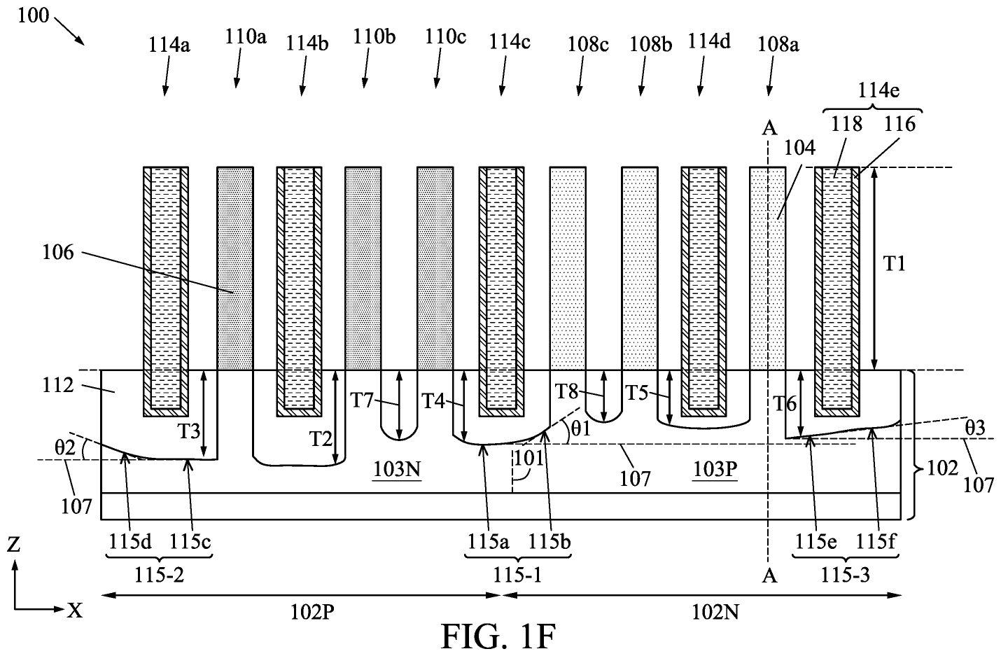

FIGS. 1-11B show exemplary sequential processes for manufacturing a semiconductor device structure 100, in accordance with some embodiments. It is understood that additional operations can be provided before, during, and after processes shown by FIGS. 1-11B and some of the operations described below can be replaced or eliminated, for additional embodiments of the method. The order of the operations/processes may be interchangeable.

FIGS. 1A-1F are cross-sectional side views of various stages of manufacturing a semiconductor device structure 100, in accordance with some embodiments. As shown in FIG. 1A, a first semiconductor layer 104 is formed on a substrate 102. In some embodiments, the substrate 102 is a bulk semiconductor substrate, such as a semiconductor wafer. For example, the substrate 102 is a silicon wafer. The substrate 102 may include silicon or another elementary semiconductor material such as germanium. In some other embodiments, the substrate 102 includes a compound semiconductor. The compound semiconductor may include gallium arsenide, silicon carbide, indium arsenide, indium phosphide, another suitable semiconductor material, or a combination thereof. In some embodiments, the substrate 102 is a semiconductor-on-insulator (SOI) substrate. The SOI substrate may be fabricated using a separation by implantation of oxygen (SIMOX) process, a wafer bonding process, another applicable method, or a combination thereof.

In FIG. 1A, the substrate 102 has a P-type metal-oxide-semiconductor region 102P (PMOS region 102P) and an N-type metal-oxide-semiconductor region 102N (NMOS region 102N) adjacent to the PMOS region 102P, in accordance with some embodiments. The PMOS region 102P may be used to form a PMOS structure thereon, and the NMOS region 102N may be used to form an NMOS structure thereon. In some embodiments, an N-well region 103N and a P-well region 103P are formed in the substrate 102, as shown in FIG. 1A. In some embodiments, the N-well region 103N is formed in the substrate 102 in the PMOS region 102P, whereas the P-well region 103P is formed in the substrate 102 in the NMOS region 102N, as shown in FIG. 1A. The N-well region 103N may be physically separated from the P-well region 103P by a divider 101, and any number of device features (e.g., other active devices, doped regions, isolation structures, etc.) may be disposed between the PMOS region 102P and the NMOS region 102N. In some embodiments, separate ion implantation processes may be performed to form the P-well region 103P and the N-well region 103N. For example, the N-well region 103N may be formed in the PMOS region 102P by covering the NMOS region 102N with a mask (such as a photoresist, an oxide, or the like) and performing an ion implantation process. N-type dopants, such as arsenic ions, may be implanted into the PMOS region 102P. Likewise, the P-well region 103P may be formed in the NMOS region 102N by covering the PMOS region 102P with a mask and performing an ion implantation process. P-type dopants, such as boron ions, may then be implanted into the NMOS region 102N.

In some embodiments, one or more anti-punch through (APT) implantations may be performed to implant anti-punch through dopants into the substrate 102. The anti-punch through dopants help to reduce or prevent the short channel effect of electrons or holes punching through from the source to the drain as well as drain-induced barrier lowering (DIBL). In some embodiments, the anti-punch through dopants in the N-well region 103N may be the same as the dopants in the N-well region 103N but with a higher dopant concentration, and the anti-punch through dopants (provided in a separate process) in the P-well region 103P may be the same as the P-well region 103P but with a higher dopant concentration. For example, the APT implantation may use an implantation dosage with a concentration in a range of about 1E10¹³ atoms/cm² to about 1.5E10¹⁴ atoms/cm². However, any suitable implantation and dosage may be utilized. In one exemplary embodiment, the APT implantation process for implanting anti-punch through dopants in the P-well region 103P may include: (1) implanting a p-type APT dopant (e.g., boron) into the P-well region 103P at a first implant dosage of between about 3E10¹³ atoms/cm² and about 5E10¹⁴ atoms/cm², wherein the p-type dopant may be implanted at a first kinetic energy in a range of about 3 KeV to about 10 KeV; (2) implanting a p-type dopant (e.g., boron) into the first device region 103 at a second implant dosage of between about 5E10¹³ atoms/cm² and about 4E10¹⁴ atoms/cm², wherein the p-type dopant may be implanted at a second kinetic energy in a range of about 10 KeV to about 80 KeV. However, the first implant dosage and/or first kinetic energy may be greater or less than the second implant dosage and/or second kinetic energy. Likewise, the APT implantation process for implanting anti-punch through dopants in the N-well region 103N may include: (1) implanting an n-type APT dopant (e.g., phosphorus) into the N-well region 103N at a first implant dosage of between about 3E10¹³ atoms/cm² and about 5E10¹⁴ atoms/cm², wherein the n-type dopant may be implanted at a first kinetic energy in a range of about 5 KeV to about 15 KeV; (2) implanting an n-type dopant (e.g., phosphorous) into the N-well region 103N at a second implant dosage of between about 2E10¹³ atoms/cm² and about 1E10¹⁴ atoms/cm², wherein the n-type dopant may be implanted at a second kinetic energy in a range of about 20 KeV to about 200 KeV. The first implant dosage and/or first kinetic energy may be greater or less than the second implant dosage and/or second kinetic energy.

The first semiconductor layer 104 may be made of any suitable semiconductor material, such as silicon, germanium, III-V semiconductor material, or combinations thereof. In some embodiments, the first semiconductor layer 104 is substantially made of silicon. The first semiconductor layer 104 may be formed by an epitaxial growth process, such as metal-organic chemical vapor deposition (MOCVD), metal-organic vapor phase epitaxy (MOVPE), plasma-enhanced chemical vapor deposition (PECVD), remote plasma chemical vapor deposition (RP-CVD), molecular beam epitaxy (MBE), hydride vapor phase epitaxy (HYPE), liquid phase epitaxy (LPE), chloride vapor phase epitaxy (Cl-VPE), or any other suitable process.

In FIG. 1B, the portion of the first semiconductor layer 104 disposed over the N-well region 103N is removed, and a second semiconductor layer 106 is formed over the N-well region 103N and adjacent the portion of the first semiconductor layer 104 disposed over the P-well region 103P. A patterned mask layer (not shown) may be first formed on the portion of the first semiconductor layer 104 disposed over the P-well region 103P, and the portion of the first semiconductor layer 104 disposed over the N-well region 103N may be exposed. A removal process, such as a dry etch, wet etch, or a combination thereof, may be performed to remove the portion of the first semiconductor layer 104 disposed over the N-well region 103N, and the N-well region 103N may be exposed. The removal process does not substantially affect the mask layer (not shown) formed on the portion of the first semiconductor layer 104 disposed over the P-well region 103P, which protects the portion of the first semiconductor layer 104 disposed over the P-well region 103P.

Next, the second semiconductor layer 106 is formed on the exposed N-well region 103N. The second semiconductor layer 106 may be made of any suitable semiconductor material, such as silicon, germanium, III-V semiconductor material, or combinations thereof. In some embodiments, the second semiconductor layer 106 is substantially made of silicon germanium (SiGe). For example, the second semiconductor layer 106 may be a strained SiGe layer including Ge in a range between about 25 at. % and about 50 at. %. The second semiconductor layer 106 may be formed by the same process as the first semiconductor layer 104. For example, the second semiconductor layer 106 is formed on the exposed N-well region 103N by an epitaxial growth process, which does not form the second semiconductor layer 106 on the mask layer (not shown) disposed on the first semiconductor layer 104. As a result, the first semiconductor layer 104 is disposed over the P-well region 103P in the NMOS region 102N, and the second semiconductor layer 106 is disposed over the N-well region 103N in the PMOS region 102P. Portions of the first semiconductor layer 104 may serve as channels in the subsequently formed NMOS structure in the NMOS region 102N. Portions of the second semiconductor layer 106 may serve as channels in the subsequently formed PMOS structure in the PMOS region 102P. In some embodiments, the NMOS structure and the PMOS structure are FinFETs. Other types of semiconductor devices may be utilized, such as nanosheet transistors, planar FETs, complementary FETs (CFETs), forksheet FETs, or other suitable devices.

In FIG. 1C, a plurality of fins 108a, 108b, 108c, 110a, 110b, 110c are formed. The fins 108a, 108b, 108c, 110a, 110b, 110c may be formed by etching the first semiconductor layer 104, the second semiconductor year 106, and the substrate 102 underneath using one or more mask layers patterned by any suitable method. For example, the fins 108a-c, 110a-c may be formed using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer (not shown) is formed over a substrate and patterned using a photolithography process. Spacers (not shown) are formed alongside the patterned sacrificial layer using a self-aligned process. The sacrificial layer is then removed, and the remaining spacers may then be used to pattern the fins.

The first semiconductor layer 104, the second semiconductor layer 106, the N-well/P-well regions 103N, 103P in the substrate 102 are etched to form the fins 108a-c and 110a-c using a mask (not shown). Trenches 113a-g (collectively referred to as 113) are formed between neighboring fins 108a-c and 110a-c. As will be discussed in more detail below, the trenches 113 have various depths and are formed by etching through the first semiconductor layer 104 or the second semiconductor layer 106 and into the substrate 102. The fins 108a-c may each include the first semiconductor layer 104, and a portion of the first semiconductor layer 104 may serve as an NMOS channel. Each fin 108a-c may also include the P-well region 103P. The fins 110a-c may each include the second semiconductor layer 106, and a portion of the second semiconductor layer 106 may serve as a PMOS channel. Each fin 110a-c may also include the N-well region 103N. Each fin 108a-c, 110a-c may have a height along the Z-axis ranging from about 30 nm to about 80 nm. At this stage, the NMOS channels 104c of the fins 108a-c have substantially the same height, which equals to the thickness of the first semiconductor layer 104. Similarly, the PMOS channels 106c of the fins 110a-c have substantially the same height, which equals the thickness of the second semiconductor layer 106.

In some embodiments, the fins 108a, 108b, 108c are formed so that a distance D1 between the fin 108b and fin 108c is less than a distance D2 between the fin 108b and fin 108a. The fins 110a, 110b, 110c are formed so that a distance D3 between fin 110b and fin 110c is less than a distance D4 between the fin 110b and fin 110a. In some embodiments, the fins 108a-c may be located at a ring oscillator (RO) region, and the fins 110a-c may be located at an RO region.

In some embodiments, the first semiconductor layer 104 (e.g., Si) deposited over the substrate 102 at the P-well region 103P and the second semiconductor layer 106 (e.g., SiGe) deposited over the substrate 102 at the N-well region 103N are etched at different rates when exposing to the same etchant (e.g., first and second etchants of the cyclic dry etching process to be discussed below). The semiconductor material of the first semiconductor layer 104 may have a first etch rate by the etchant while the semiconductor material of the second semiconductor layer 106 may have a second etch rate by the etchant that is faster than the first etch rate. Therefore, portions of the substrate 102 covered by the second semiconductor layer 106 at the N-well region 103N may be exposed and etched before the substrate 102 at the P-well region 103P is exposed. As a result, a difference in the substrate thickness (and therefore different fin heights) between the N-well region 103N and the P-well region 103P is formed as a result of the formation of the fins 108a-c, 110a-c. In some embodiments where the second semiconductor layer 106 includes SiGe and the first semiconductor layer 104 includes Si, the fins 108a-c at the PMOS region 102P may have heights greater than that of the fins 110a-c at the NMOS region 102N. For example, the fin 110b may have a height H1 and the fin 108b may have a height H2 that is shorter than the height H1.

Due to etch loading effects, regions with lower SiGe density (e.g., fin 110a) may be etched at a faster rate than regions with higher SiGe density (e.g., fins 110b, 110c), resulting in a further reduction of the substrate thickness at the N-well region 103N around the fin 110a. For example, the substrate 102 at the N-well region 103N between the fins 110b, 110c may have a height H3, and the substrate 102 at the N-well region 103N around the fin 110a may have a height H4 that is shorter than the height H3. Likewise, regions with lower Si density (e.g., fin 108a) may be etched at a faster rate than regions with higher Si density (e.g., fins 108b, 108c), resulting in a further reduction of the substrate thickness at the P-well region 103P around the fin 108a. For example, the substrate 102 at the P-well region 103P between the fins 108b, 108c may have a height H5, and the substrate 102 at the P-well region 103P around the fin 108a may have a height H6 that is shorter than the height H5.

In some embodiments, which can be combined with any of the embodiments of this disclosure, the one or more etch processes are performed so that the trenches in the P-well region 103P have a different depth from the trenches in the N-well region 103N due to different etching rates of the first semiconductor layer 104 and the second semiconductor layer 106. Stated differently, the bottoms of the trenches 113a-g are etched to have a different height. Here, the height of the bottom of the trenches 113a-g is defined as a distance between the bottom of the respective trench to a bottom of the substrate 102. In one exemplary embodiment, the trench 113a is located at or near the divider 101 and cross over the P-well region 103P and the N-well region 103N, and the trench 113f between the fin 110a and fin 110b may have a bottom at a first height, the trench 113e immediately adjacent to the fin 110a and away from the fin 110b may have a bottom at a second height that is higher than the first height, the trench 113g immediately adjacent to the fin 110b and away from the fin 110a may have a bottom at a third height that is greater than the second height, the trench 113a between the fin 110c and the fin 108c may have a bottom at a fourth height that is between the second height and the third height, the trench 113b between the fin 108c and the fin 108b may have a bottom at a fifth height that is greater the third height, the trench 113c between the fin 108b and fin 108a may have a bottom at a sixth height that is between the third height and the fifth height, and the trench 113d immediately adjacent to the fin 108a and away from the fin 108b may have a bottom at a seventh height that is between the fourth height and the sixth height.

In some embodiments, which can be combined with any of the embodiments of this disclosure, the one or more etch processes are performed so that bottoms of the trenches at the P-well and N-well regions 103P, 103N are etched to have a slope (i.e., inclined surface). In one exemplary embodiment, the bottom of each of the trenches 113c, 113d is slanted towards the divider 101 at a downward angle, and the bottom of each of the trenches 113e, 113f is slanted towards the divider 101 at a downward angle. In some embodiments, the substrate 102 at or near the divider 101 may have a first substrate thickness and the N-well region 103N of the substrate 102 at or near the divider 101 may have a second substrate thickness T2 that is shorter than the first substrate thickness. The difference in substrate thickness at P-well and N-well regions 103P, 103N results in the bottom of the trench 113a to slope towards the N-well region 103N. In some embodiments, the bottom of the trenches 113a-g may have rounded corners. In some embodiments, the bottom of the trenches 113a-g may have convex or concave surface profile as the result of the one or more etch processes performed to form the fins 108a-c and 110a-c.

In some embodiments, which can be combined with any of the embodiments of this disclosure, the one or more etch processes (e.g., etch-deposition process to be discussed below) are performed so that the fins 108a-c and 110a-c are etched to have vertical sidewalls and linear edges. In some embodiments, the fins 108a-c and 110a-c may be etched so that an upper portion (e.g., the first and second semiconductor layers 104, 106) of the fins 108a-c and 110a-c has a greater width than that of a lower portion (e.g., N-well and P-well regions 103N, 103P) of the fins 108a-c and 110a-c. FIG. 1C-1 illustrates an enlarged view of a portion of the semiconductor device structure 100 in accordance with some embodiments. As shown in FIG. 1C-1, the first semiconductor layer 104 of the fin 108c has a width W1 and the P-well region 103P has a width W2 greater than the width W1, and the second semiconductor layer 106 of the fin 110c has a width W3 and the N-well region 103N has a width W4 greater than the width W3. In some embodiments, the etch process may be performed so that each of the first and second semiconductor materials 104, 106 (i.e., NMOS and PMOS channels) has a substantial uniform width (e.g., vertical profile) along the body of the first and second semiconductor materials 104, 106, and each of the N-well and P-well regions 103N, 103P has a width gradually increased in a direction away from the first and second semiconductor materials 104, 106. Having the upper portion of the fins 108a-c and 110a-c formed with a uniform width ensures the NMOS and PMOS channels have a uniform critical dimension (CD) for better device performance.

The fins 108a-c and 110a-c may be formed by one or more etch processes. In some embodiments, the fins 108a-c and 110a-c are formed by an etch-deposition process including a dry etching process and an oxidation process. The dry etching process may be any acceptable etch technique, such as a reactive ion etch (RIE), a neutral beam etch (NBE), the like, or a combination thereof. In some embodiments, the dry etching process may include a first plasma etching process that employs a first etchant containing a first halogen element to etch the first and second semiconductor materials 104, 106 as well as the N-well and P-well regions 103N, 103P of the fins 108a-c and 110a-c. In one embodiment, the first etchant is a chlorine-based etch chemistry, which can adsorb on and react with the first and second semiconductor materials 104, 106 as well as the N-well and P-well regions 103N, 103P. Exemplary chlorine-based etch chemistry may include, but are not limited to, Cl₂, CHCl₃, CCl₄, BCl₃, or the like, or a combination thereof. The first plasma etching process may further include a hydrogen-containing etchant such as hydrogen-based chemistry to increase the etch rate for etching the first and second semiconductor materials 104, 106 as well as the N-well and P-well regions 103N, 103P. In some embodiments, an RF bias power may be supplied (to a pedestal upon which the semiconductor device structure 100 is disposed) during the first plasma etching process, the removal of the first and second semiconductor materials 104, 106 as well as the N-well and P-well regions 103N, 103P to enable anisotropic etching.

The dry etching process also includes a second plasma etching process for etching the first and second semiconductor materials 104, 106 as well as the N-well and P-well regions 103N, 103P of the fins 108a-c and 110a-c. The second plasma etching process uses a second etchant containing a second halogen element. In one embodiment, the second etchant is a fluorine-based etch chemistry, which facilitate the reaction of the first and second semiconductor materials 104, 106 as well as the N-well and P-well regions 103N, 103P with portions of the first etchant previously adsorbed on the surface of the first and second semiconductor materials 104, 106 as well as the N-well and P-well regions 103N, 103P of the fins 108a-c and 110a-c. Exemplary fluorine-containing gas may include, but are not limited to, CF₄, SF₆, CH₂F₂, C₂H₄F₂, CHF₃, C₂F₆, or the like, or a combination thereof. The second plasma etching process ensures the upper portion (e.g., the first and second semiconductor layers 104, 106) of the fins 108a-c and 110a-c has a greater width than the lower portion (e.g., N-well and P-well regions 103N, 103P) of the fins 108a-c and 110a-c. During the second plasma etching process, the RF bias power may or may not be used. In some embodiments, the RF bias power is not used during the second plasma etching process. The first plasma etching process may be performed for a first period of time (T1) and the second plasma etching process may be performed for a second period of time (T2), and the ratio of T1:T2 may be about 3:1 to about 6:1.

The oxidation process may be performed to form an oxide layer on the exposed surfaces of the first and second semiconductor materials 104, 106 as well as the N-well and P-well regions 103N, 103P. The oxidation process may form a silicon oxide layer on the first and second semiconductor materials 104, 106 as well as the N-well and P-well regions 103N, 103P. The silicon oxide layer helps shrink the critical dimension (CD) of the openings between the fins 108a-c and 110a-c so that the openings are extended into the substrate portions with a proper CD. The oxidation process may be performed following the dry etching process. In some embodiments, the oxidation process may be performed between the first and second plasma etching processes. For example, the oxidation process may be performed in any of the following order: (1) first plasma etching process—second plasma etching process—oxidation process; (2) first plasma etching process—oxidation process—second plasma etching process; and (3) first plasma etching process—oxidation process—second plasma etching process—oxidation process. In some embodiments, the dry etching process and the oxidation process are performed in a cyclic manner in any order discussed above. The cyclic process may be repeated 2 to 5 cycles. More or less is contemplated depending on the application. In one exemplary embodiment, the first and second semiconductor materials 104, 106 as well as the N-well and P-well regions 103N, 103P are etched through a cyclic process in the order of first plasma etching process—second plasma etching process—oxidation process, and such cyclic process may be repeated 2 to 10 cycles.

The RF bias power and the cyclic process of the dry etching process and the oxidation process provide combined etching effect such that the upper portion of the fins 108a-c and 110a-c is removed at greater amount than the lower portion of the fins 108a-c and 110a-c, resulting in each of the first and second semiconductor materials 104, 106 (i.e., NMOS and PMOS channels) with a substantial uniform width and each of the N-well and P-well regions 103N, 103P of the fins 108a-c and 110a-c with a width gradually increased in a direction away from the first and second semiconductor materials 104, 106.

In FIG. 1D, an insulating material 112 is formed between adjacent fins 108a-c, 110a-c. The insulating material 112 may be first formed between adjacent fins 108a-c, 110a-c and over the fins 108a-c, 110a-c, so the fins 108a-c, 110a-c are embedded in the insulating material 112. A planarization process, such as a chemical-mechanical polishing (CMP) process may be performed to expose the top of the fins 108a-c, 110a-c, as shown in FIG. 1D. In some embodiments, the planarization process exposes the top of the mask (not shown) disposed on the fins 108a-c and 110a-c. The insulating material 112 may include an oxygen-containing material, such as silicon oxide, carbon or nitrogen doped oxide, or fluorine-doped silicate glass (FSG); a nitrogen-containing material, such as silicon nitride, silicon oxynitride (SiON), SiOCN, SiCN; a low-K dielectric material (e.g., a material having a K value lower than that of silicon dioxide); or any suitable dielectric material. The insulating material 112 may be formed by any suitable method, such as low-pressure chemical vapor deposition (LPCVD), plasma enhanced CVD (PECVD) or flowable CVD (FCVD).

In FIG. 1E, a plurality of dielectric features 114a, 114b, 114c, 114d, 114e are formed in the insulating material 112. In some embodiments, each dielectric feature 114a, 114b, 114c, 114d, 114e may include a liner 116 and a low-K dielectric material 118. The dielectric features 114a-e may be referred to as hybrid fins. The liner 116 may include a dielectric material such as SiO₂, SiN, SiCN, SiOC, SiOCN, or other suitable dielectric material. In some embodiments, the liner 116 includes SiCN. The liner 116 may be formed by a conformal process, such as an ALD process. The low-K dielectric material 118 may be formed on the liner 116 and between adjacent fins 108a-c, 110a-c. The low-K dielectric material 118 may include silicon, oxygen, hydrogen, and/or combinations thereof. The low-K dielectric material 118 may have a K value less than about 3.5. The low-K dielectric material 118 may be formed by any suitable process, such as CVD or FCVD. The dielectric features 114a-e may be dielectric fins that separate subsequently formed source/drain (S/D) epitaxial features and electrode layers. In some embodiments, each dielectric feature 114a-e has a width W5 ranging from about 10 nm to about 30 nm. In some embodiments, the dielectric features 114a-e may have a height along the Z-axis greater than, equal to, or less than a height of the fins 108a-c, 110a-c. The bottoms of the dielectric features 114a-e are at the same elevation. However, the different heights of the bottom of the trenches 113a-g (FIG. 1C) may result in a varying distance between the bottom of the dielectric features 114a-e and the respective bottom of the trenches 113a-g.

In FIG. 1F, the insulating material 112 may be recessed by removing a portion of the insulating material 112 located on both sides of each fin 108a-c, 110a-c. The insulating material 112 may be recessed by any suitable removal process, such as dry etch or wet etch that selectively removes the insulating material 112 but does not substantially affect the semiconductor materials of the fins 108a-c, 110a-c, the liner 116, and the low-K dielectric material 118. The recessed insulating material 112 may be the shallow trench isolation (STI). In some embodiments, the insulating material 112 is recessed so that the top surface of the insulating material 112 is at or near an elevation of the interface between the first semiconductor layer 104 and the N-well region 103N (or the second semiconductor layer 106 and the P-well region 103P).

After the insulating material 112 is recessed, portions of the dielectric features 114a-e, first semiconductor layers 104, the second semiconductor layers 106 are exposed. The exposed first and second semiconductor layers 104, 106 may have a height T1 in a range of about 30 nm to about 80 nm. Due to various depths of the trenches 113a-g, the recessed insulating material 112 (i.e., STI) at the N-well and P-well regions 103N, 103P have different heights. In one exemplary embodiment, the STI between the fin 110a and fin 110b may have a height T2, the STI immediately adjacent to the fin 110a and away from the fin 110b may have a height T3 that is shorter than the height T2, the STI between the fin 110b and the fin 110c may have a height T7 that is shorter than the height T3, the STI between the fin 110c and the fin 108c may have a height T4 that is between the height T3 and the height T7, the STI between the fin 108c and the fin 108b may have a height T8 that is shorter than T7, the STI between the fin 108b and fin 108a may have a height T5 that is between the height T7 and the height T8, and the STI immediately adjacent to the fin 108a and away from the fin 108b may have a height T6 that is between the height T4 and the height T5.

In some embodiments, the height T2 may be in a range of about 60 nm to about 70 nm, the height T3 may be in a range of about 55 nm to about 65 nm, the height T7 may be in a range of about 45 nm to about 55 nm, the height T4 may be in a range of about 50 nm to about 60 nm, the height T8 may be in a range of about 35 nm to about 45 nm, the height T5 may be in a range of about 40 nm to about 50 nm, the height T6 may be in a range of about 45 nm to about 55 nm.

Due to the difference in substrate thickness at P-well and N-well regions 103P, 103N at or near the divider 101, the bottom of the trench 113a (FIG. 1C) has a sloped slanted from the P-well region 103P down to the N-well region 103N. In some embodiments, which can be combined with any other embodiments of this disclosure, the STI formed in the trench 113a between the fin 108c and the fin 110c has an angled bottom 115-1, in which a first bottom part 115a (in the P-well region 103P) has a rounded corner disposed at a first elevation, and a second bottom part 115b (in the N-well region 103N) has a rounded corner disposed at a second elevation higher than the first elevation. The second bottom part 115b forms an angle θ1 of about 6 degrees to about 30 degrees with respect to a horizontal line 107 extended along a direction parallel to the top surface 112t. In some embodiments, which can be combined with any other embodiments of this disclosure, the STI formed in the trench 113e (FIG. 1C) has an angled bottom 115-2, in which a first bottom part 115c (in the N-well region 103N and towards the fin 110a) has a rounded corner disposed at a first elevation, and a second bottom part 115d (in the N-well region 103N and away from the fin 110a) has a rounded corner disposed at a second elevation higher than the first elevation. The second bottom part 115c forms an angle θ2 of about 6 degrees to about 30 degrees with respect to a horizontal line 107 extended along a direction parallel to the top surface 112t. In some embodiments, which can be combined with any other embodiments of this disclosure, the STI formed in the trench 113d (FIG. 1C) has an angled bottom 115-3, in which a first bottom part 115e (in the P-well region 103P and towards the fin 108a) has a rounded corner disposed at a first elevation, and a second bottom part 115f (in the P-well region 103P and away from the fin 108a) has a rounded corner disposed at a second elevation higher than the first elevation. The second bottom part 115c forms an angle θ3 of about 6 degrees to about 30 degrees with respect to a horizontal line 107 extended along a direction parallel to the top surface 112t.

Since the STIs 112 are formed with bottoms at different slopes and heights in N-well and/or P-well regions 103N, 103P of the substrate 102, the APT dopants in the N-well or P-well portion of fins 108a-c, 110a-c can extend different depths within the STI to help reduce or prevent the short channel effect of electrons or holes punching through from the source to the drain. As a result, isolation leakage is controlled and the device performance is improved.

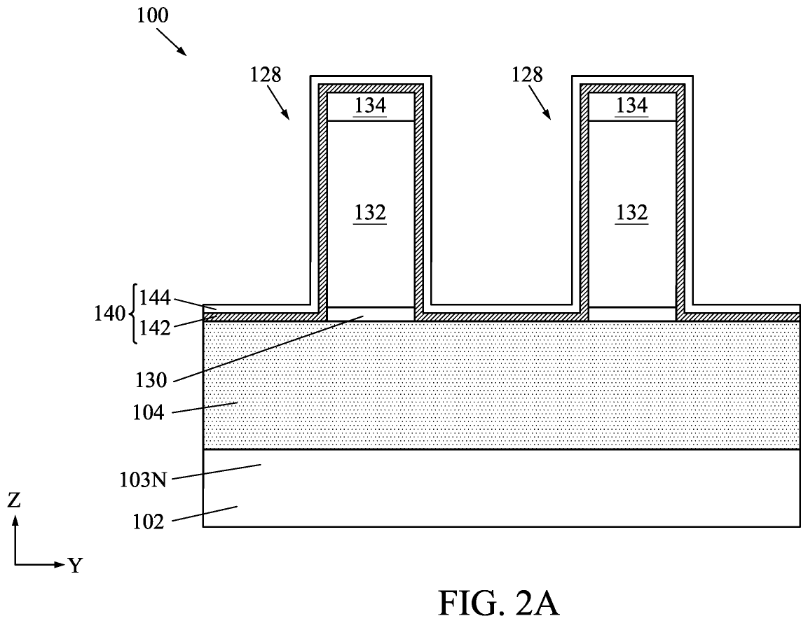

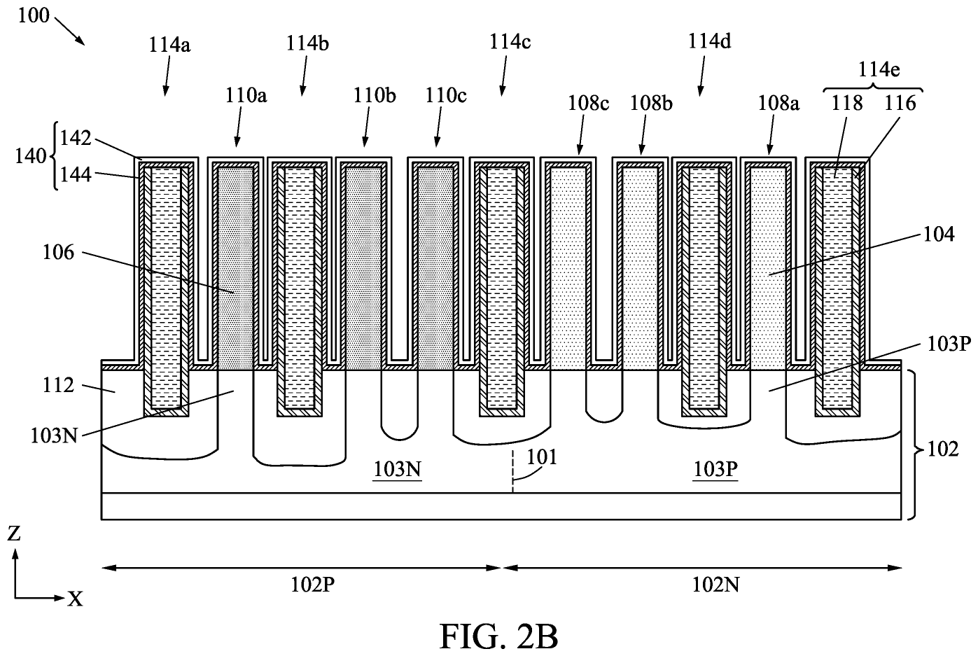

FIGS. 2A-7A are cross-sectional side views of various stages of manufacturing the semiconductor device structure 100 of FIG. 1F taken along line A-A, in accordance with some embodiments. FIGS. 2B-7B are cross-sectional side views of various stages of manufacturing the semiconductor device structure 100 of FIG. 1F, in accordance with some embodiments. In FIGS. 2A and 2B, one or more sacrificial gate stacks 128 are formed on a portion of the fins 108a-c, 110a-c and dielectric features 114a-e, and a spacer 140 is formed on the sacrificial gate stacks 128, the exposed portions of the dielectric features 104a-e, the exposed portions of the second semiconductor layer 106, the exposed portions of the first semiconductor layer 104, and the insulating material 112. Each sacrificial gate stack 128 may include a sacrificial gate dielectric layer 130, a sacrificial gate electrode layer 132, and a mask structure 134. The sacrificial gate dielectric layer 130 may include one or more layers of dielectric material, such as SiO₂, SiN, a high-K dielectric material, and/or other suitable dielectric material. In some embodiments, the sacrificial gate dielectric layer 130 includes a material different from that of the insulating material 112. In some embodiments, the sacrificial gate dielectric layer 130 may be deposited by a CVD process, a sub-atmospheric CVD (SACVD) process, a FCVD process, an ALD process, a PVD process, or other suitable process. The sacrificial gate electrode layer 132 may include polycrystalline silicon (polysilicon). The mask structure 134 may include an oxygen-containing layer and a nitrogen-containing layer. In some embodiments, the sacrificial gate electrode layer 132 and the mask structure 134 are formed by various processes such as layer deposition, for example, CVD (including both LPCVD and PECVD), PVD, ALD, thermal oxidation, e-beam evaporation, or other suitable deposition techniques, or combinations thereof.

The sacrificial gate stacks 128 may be formed by first depositing blanket layers of the sacrificial gate dielectric layer 130, the sacrificial gate electrode layer 132, and the mask structure 134, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the sacrificial gate stacks 128, the fins 108a-c, 110a-c are partially exposed on opposite sides of the sacrificial gate stacks 128. As illustrated in FIG. 2A, two sacrificial gate stacks 128 are formed, which is for illustrative purpose and not intended to be limiting beyond what is specifically recited in the claims. It can be appreciated that any number of the sacrificial gate stacks 128 may be formed. The sacrificial gate stacks 128 may also cover a portion of each of the dielectric features 104a-e, and the dielectric features 104a-e are partially exposed on opposite sides of the sacrificial gate stacks 128.

In some embodiments, the spacer 140 includes a first layer 142 and a second layer 144, as shown in FIGS. 2A and 2B. The first and second layers 142, 144 may be conformally deposited on the exposed surfaces of the semiconductor device structure 100. The conformal first and second layers 142, 144 may be formed by ALD processes. The first and second layers 142, 144 may be made of a dielectric material such as silicon oxide, silicon nitride, silicon carbide, silicon oxynitride, SiCN, silicon oxycarbide, SiOCN, and/or combinations thereof. In some embodiments, the first and second layers 142, 144 include different materials. In some embodiments, the spacer 140 is a single layer. In some embodiments, the spacer 140 includes more than two layers. As shown in FIG. 2B, the spacer 140 is also formed on the exposed portions of the second semiconductor layer 106 and the dielectric features 104a-e.

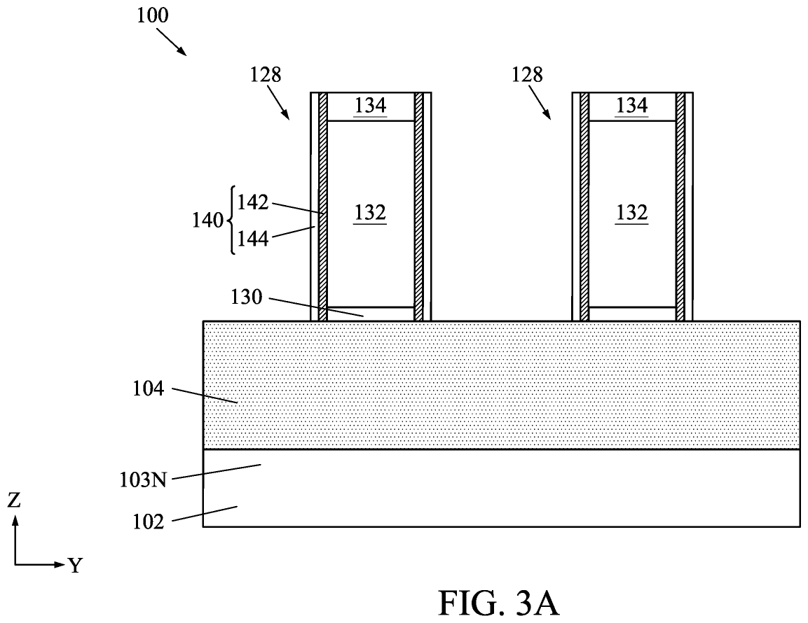

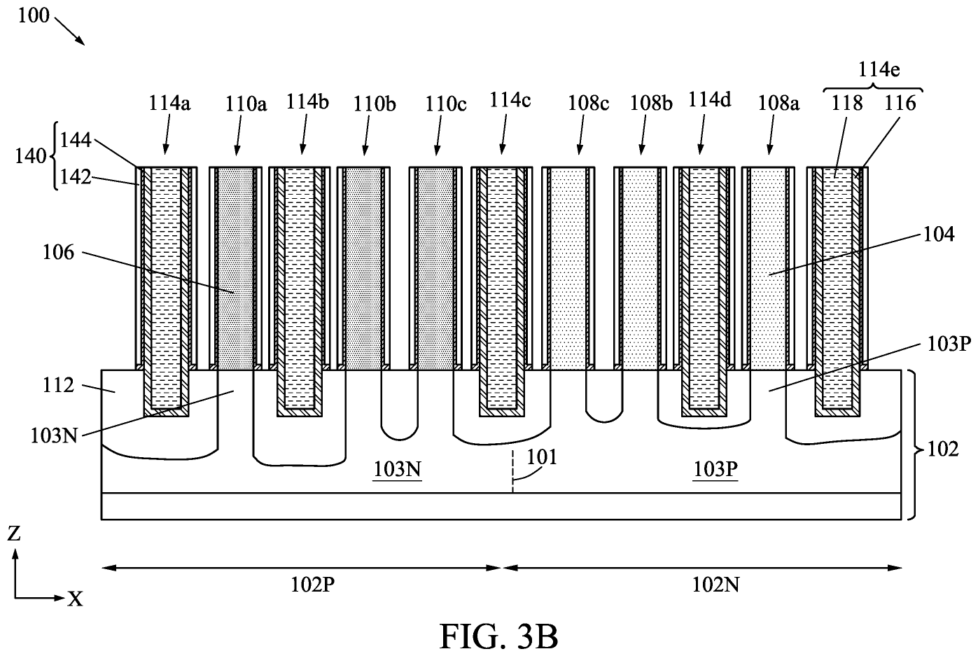

In FIGS. 3A and 3B, an anisotropic etch is performed on the spacer 140 using, for example, RIE. During the anisotropic etch process, most of the spacer 140 is removed from horizontal surfaces, such as tops of the sacrificial gate stacks 128, tops of the fins 108a-c, 110a-c, and tops of the dielectric features 114a-e, leaving the spacer 140 on the vertical surfaces, such as the sidewalls of sacrificial gate stacks 128, sidewalls of the fins 108a-c, 110a-c, and sidewalls of the dielectric features 114a-e.

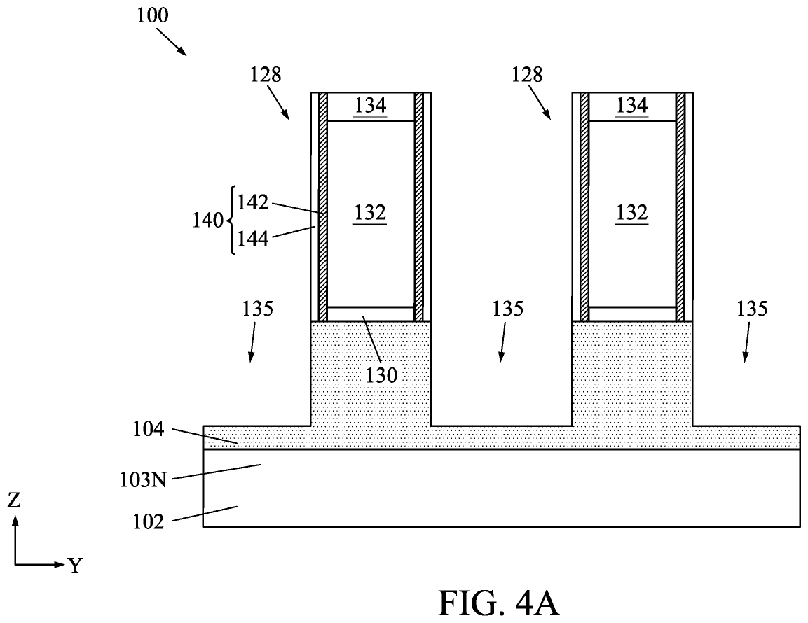

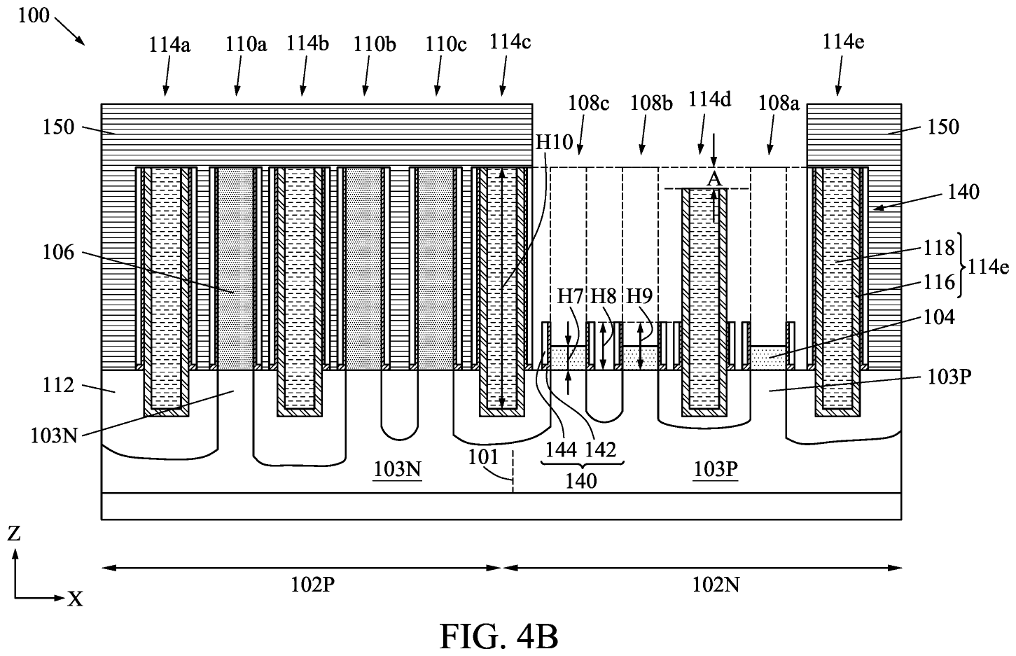

In FIGS. 4A and 4B, a mask 150 is formed on the PMOS region 102P and on the dielectric feature 114e which may separate the NMOS region 102N from another PMOS region 102P (not shown), and the exposed materials not covered by the sacrificial gate stacks 128 and the mask 150, such as exposed portions of the fins 108a-c, the dielectric feature 114d, and the spacer 140 disposed on the sidewalls of the fins 108a-c and the dielectric feature 114d, are recessed to form openings 135. A sacrificial liner (not shown) may be formed on the PMOS region 102P and the dielectric feature 114e, and the mask 150 is formed on the sacrificial liner. The mask 150 may be a patterned photoresist layer. As shown in FIG. 4B, the fins 108a-c covered by the sacrificial gate stacks 128 are shown in dotted lines. The recess of the materials may be performed by multiple etch processes. For example, a first etch process is performed to recess the spacer 140, a second etch process is performed to recess the fins 108a-c, and an optional third etch process is performed to recess the dielectric feature 114d. The recessing of the spacer 140, the fins 108a-c, and the dielectric feature 114d may be performed in any suitable order. In some embodiments, the first etch process is a selective etch process that recesses the spacer 140 but not the other materials of the semiconductor device structure 100, the second etch process is a selective etch process that recesses the fins 108a-c but not the other materials of the semiconductor device structure 100, and the optional third etch process is a selective etch process that recesses the dielectric feature 114d but not the other materials of the semiconductor device structure 100. In some embodiments, the three selective etch processes are plasma etch processes. Separate selective etch processes to recess the features lead to improved controlling of the dimensions of the resulting features.

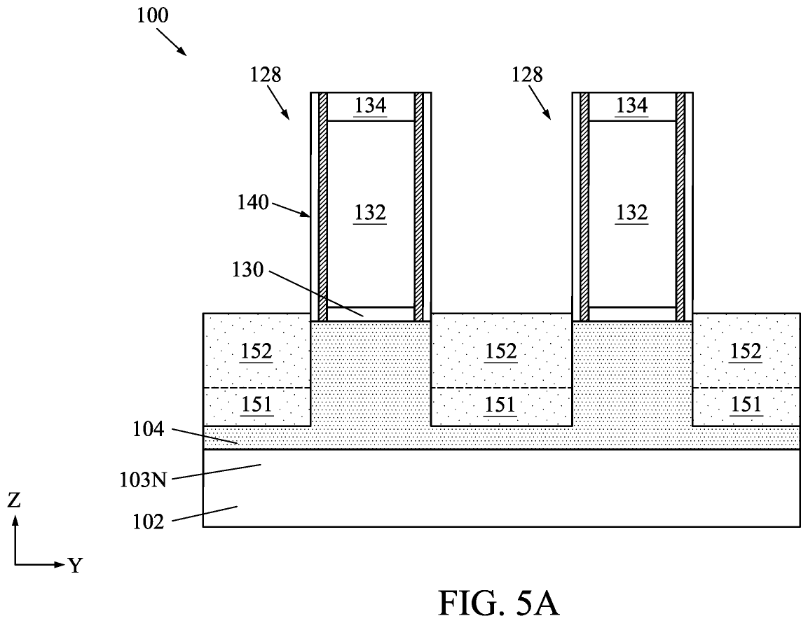

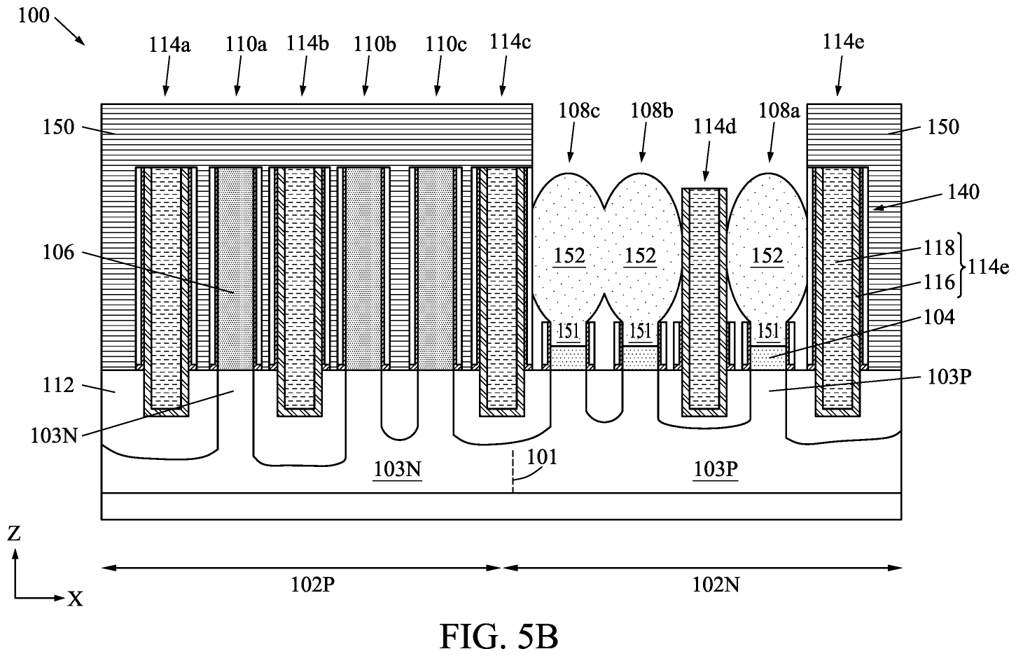

In some embodiments, the remaining fins 108a-c has a height H7 ranging from about 5 nm to about 10 nm. The remaining first layer 142 has a height H8 ranging from about 15 nm to about 20 nm, and the remaining second layer 144 has a height H9 ranging from about 10 nm to about 15 nm. In some embodiments, the top of the remaining second layer 144 may be about 1 nm to about 5 nm lower than the top of the remaining first layer 142, and such a difference in height may be used to control the shape of the subsequently formed S/D epitaxial features 152 (FIGS. 5A and 5B). The initial dielectric feature 114a-e may have a height H10 ranging from about 30 nm to about 80 nm. In some embodiments, the optional third etch process may remove an amount “A” of the exposed dielectric feature 114d. In such cases, the amount “A” may equal to a height of about 15 nm to about 40 nm. In some embodiments, the exposed dielectric feature 114d may have a decreased width as a result of the optional third etch process. The width of the exposed dielectric feature 114d may be about 25 percent to about 50 percent of the width of the initial dielectric feature 114d to help control the width of the S/D epitaxial features 152 (FIGS. 5A and 5B). In some embodiments, the liner 116 of the dielectric feature 114d has a first portion having a first thickness and a second portion disposed below the first portion having a second thickness substantially greater than the first thickness.

As shown in FIGS. 5A and 5B, lightly doped epitaxial layers 151 and the S/D epitaxial features 152 are formed. In some embodiments, each lightly doped epitaxial layers 151 may include SiP or SiAs and each S/D epitaxial features 152 may include one or more layers of Si, SiP, SiC, or SiCP for NMOS devices. In some embodiments, the lightly doped epitaxial layer 151 includes SiP or SiAs doped with phosphorous having a dopant concentration ranging from about 1E20 at/cm³ to about 5E20 at/cm³. The S/D epitaxial feature 152 may include a main layer and a cap layer. In some embodiments, the main layer includes SiP with phosphorous concentration ranging from about 5E20 at/cm³ to about 4E21 at/cm³, and the cap layer includes SiP with phosphorous concentration ranging from about 1E21 at/cm³ to about 2E21 at/cm³. The main layer may have a thickness along the Z axis ranging from about 30 nm to about 60 nm, and the cap layer may have a thickness ranging from about 5 nm to about 10 nm.

The lightly doped layers 151 and the S/D epitaxial features 152 may be formed by any suitable method, such as CVD, CVD epitaxy, MBE, or other suitable method. The lightly doped layers 151 and the S/D epitaxial features 152 may be formed on the remaining portion of the first semiconductor layer 104 of the fins 108a-c on both sides of each sacrificial gate stack 128, as shown in FIGS. 5A and 5B.

In some embodiments, the S/D epitaxial features 152 formed over the remaining portion of the first semiconductor layer 104 of the fins 108b and 108c are merged, as shown in FIG. 5B, and the S/D epitaxial feature 152 formed over the remaining portion of the first semiconductor layer 104 of the fin 108a is separated from the S/D epitaxial feature 152 formed over the remaining portion of the first semiconductor layer 104 of the fin 108b by the dielectric feature 114d. In some embodiments, the two merged S/D epitaxial features 152 and one separate S/D epitaxial feature 152 are part of a ring oscillator (RO) device.

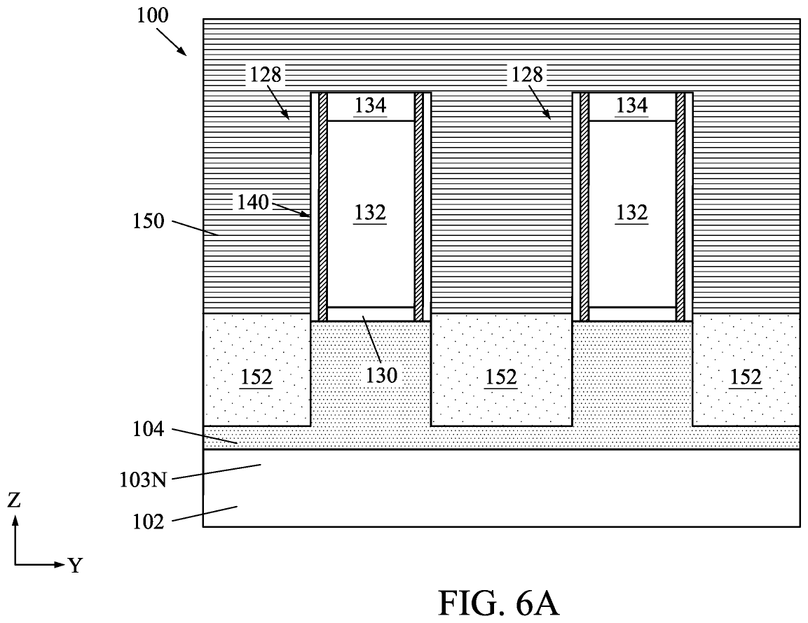

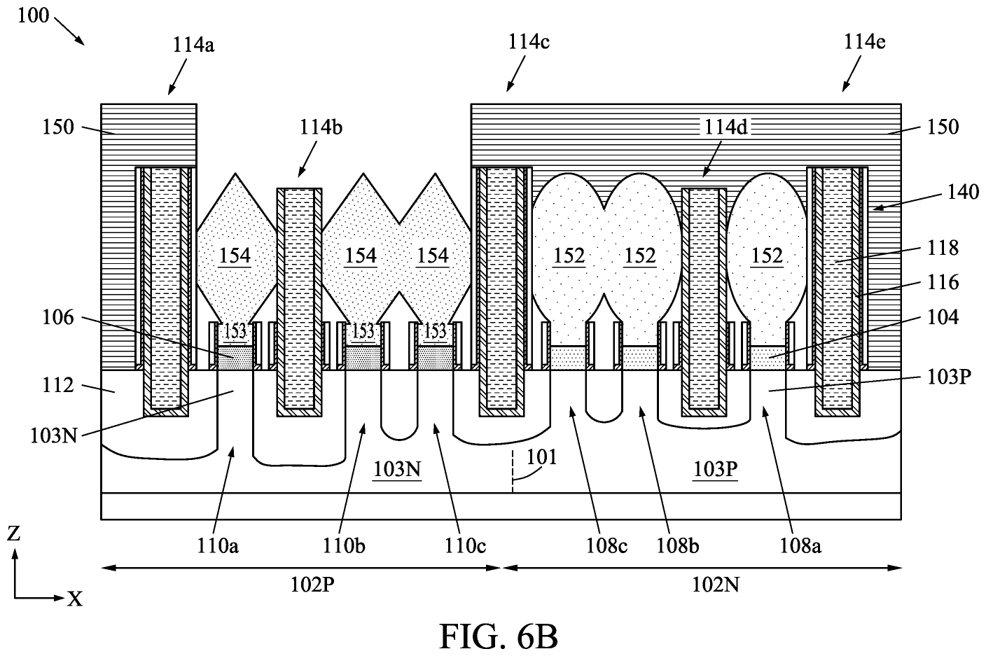

In FIGS. 6A and 6B, the mask 150 formed on the PMOS region 102P is removed to expose the fins 110a-c (FIG. 5B) and the dielectric feature 114b (FIG. 5B), and the mask 150 is formed on the NMOS region 102N and on the dielectric features 114a, 114c, 114e. Next, the exposed materials not covered by the sacrificial gate stacks 128 and the mask 150, such as exposed portions of the fins 110a-c, the dielectric feature 114b, and the spacer 140 disposed on the sidewalls of the fins 110a-c and the dielectric feature 114b, are recessed. The recess of the materials may be performed by the same processes described in FIGS. 4A and 4B. For example, a first etch process is performed to recess the spacer 140, a second etch process is performed to recess the fins 110a-c, and an optional third etch process is performed to recess the dielectric feature 114b. The recessing of the spacer 140, the fins 110a-c, and the dielectric feature 114b may be performed in any suitable order. In some embodiments, the first etch process is a selective etch process that recesses the spacer 140 but not the other materials of the semiconductor device structure 100, the second etch process is a selective etch process that recesses the fins 110a-c but not the other materials of the semiconductor device structure 100, and the optional third etch process is a selective etch process that recesses the dielectric feature 114b but not the other materials of the semiconductor device structure 100. In some embodiments, the three selective etch processes are plasma etch processes. Separate selective etch processes to recess the features lead to improved controlling of the dimensions of the resulting features. The dimensions of the fins 110a-c, the first layer 142, the second layer 144, and the dielectric feature 114b after the etch processes may have dimensions similar to those of the fins 108a-c, the first layer 142, the second layer 144, and the dielectric feature 114d shown in FIG. 4B.

As shown in FIGS. 6A and 6B, lightly doped epitaxial layers 153 and S/D epitaxial features 154 are formed. In some embodiments, each lightly doped epitaxial layers 153 may include SiGe:B and each S/D epitaxial features 154 may include one or more layers of Si, SiGe, or Ge for PMOS devices. In some embodiments, the lightly doped epitaxial layer 153 includes boron doped SiGe with a dopant concentration ranging from about 1E20 at/cm³ to about 8E20 at/cm³. The germanium concentration may range from about 15 atomic percent to about 35 atomic percent. The S/D epitaxial feature 154 may include a main layer and a cap layer. In some embodiments, the main layer includes boron doped SiGe with boron concentration ranging from about 8E20 at/cm³ to about 3E21 at/cm³, and the germanium concentration of the main layer ranges from about 35 atomic percent to about 55 atomic percent. The cap layer includes boron doped SiGe with boron concentration ranging from about 1E21 at/cm³ to about 2E21 at/cm³, and the germanium concentration of the cap layer ranges from about 45 atomic percent to about 55 atomic percent. The main layer may have a thickness along the Z axis ranging from about 30 nm to about 60 nm, and the cap layer may have a thickness ranging from about 5 nm to about 10 nm.

The lightly doped epitaxial layers 153 and the S/D epitaxial features 154 may be formed by any suitable method, such as CVD, CVD epitaxy, MBE, or other suitable method. The lightly doped epitaxial layers 153 and the S/D epitaxial features 154 may be formed on the remaining portion of the second semiconductor layer 106 of the fins 110a-c on both sides of each sacrificial gate stack 128, as shown in FIGS. 6A and 6B. In some embodiments, the lightly doped epitaxial layers 153 are not formed, and the S/D epitaxial features 154 are directly formed on the remaining portion of the second semiconductor layer 106 of the fins 110a-c on both sides of each sacrificial gate stack 128.

In some embodiments, the S/D epitaxial features 154 formed over the remaining portion of the second semiconductor layer 106 of the fins 110b and 110c are merged, as shown in FIG. 6B, and the S/D epitaxial feature 154 formed over the remaining portion of the second semiconductor layer 106 of the fin 110a is separated from the S/D epitaxial feature 152 formed over the remaining portion of the second semiconductor layer 106 of the fin 110b by the dielectric feature 114b. In some embodiments, the two merged S/D epitaxial features 154 and one separate S/D epitaxial feature 154 are part of an RO device.

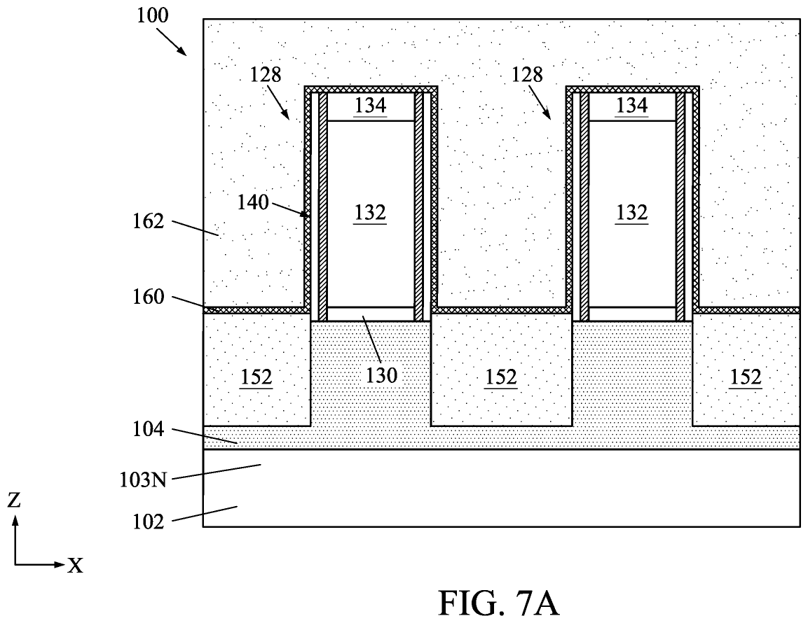

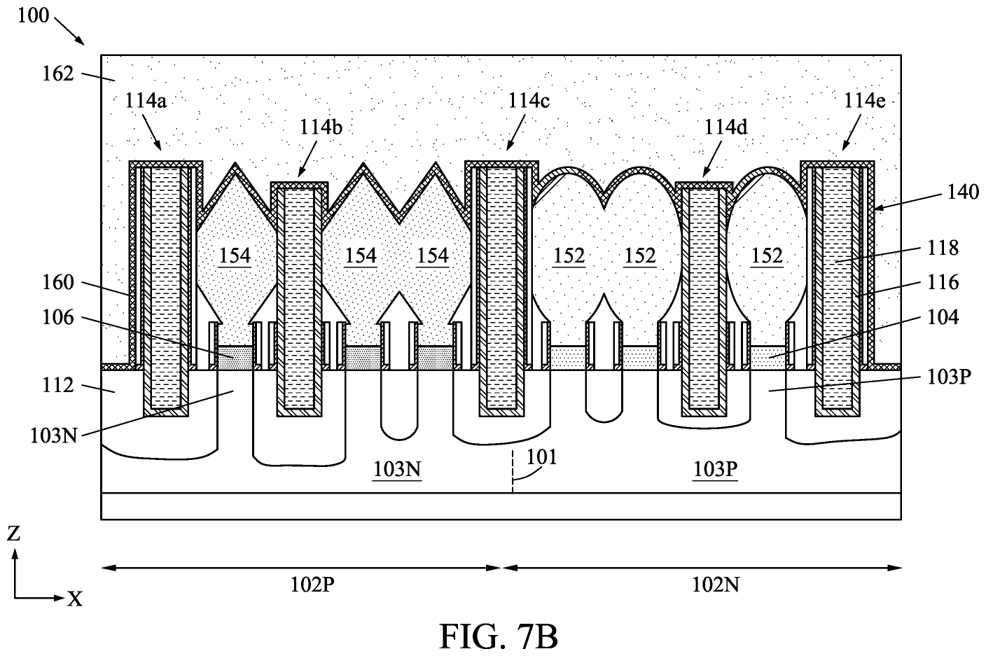

In FIGS. 7A and 7B, a contact etch stop layer (CESL) 160 may be formed on the S/D epitaxial features 152, 154 and the dielectric features 114a-e. The CESL 160 may include an oxygen-containing material or a nitrogen-containing material, such as silicon nitride, silicon carbon nitride, silicon oxynitride, carbon nitride, silicon oxide, silicon carbon oxide, the like, or a combination thereof. The CESL 160 may be formed by CVD, PECVD, ALD, or any suitable deposition technique. In some embodiments, the CESL 160 is a conformal layer formed by the ALD process. An interlayer dielectric (ILD) layer 162 may be formed on the CESL 160. The ILD layer 162 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 162 may be deposited by a PECVD process or other suitable deposition technique. In some embodiments, after formation of the ILD layer 162, the semiconductor device structure 100 may be subject to a thermal process to anneal the ILD layer 162.

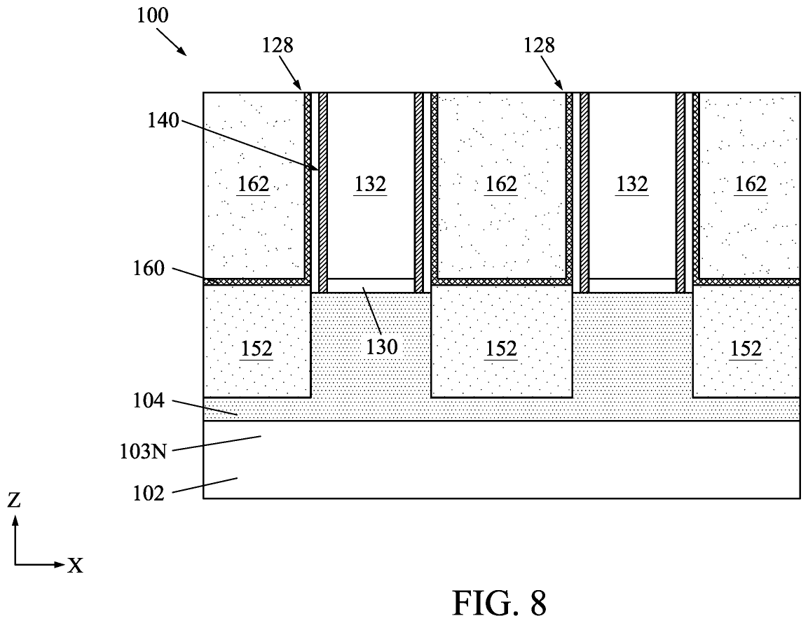

FIG. 8 is a cross-sectional side view of one of various stages of manufacturing the semiconductor device structure 100, in accordance with some embodiments. In FIG. 8, a planarization process is performed to expose the sacrificial gate electrode layer 132. The planarization process may be any suitable process, such as a CMP process. The planarization process removes portions of the ILD layer 162 and the CESL 160 disposed on the sacrificial gate stacks 128. The planarization process may also remove the mask structure 134 (FIG. 7A).

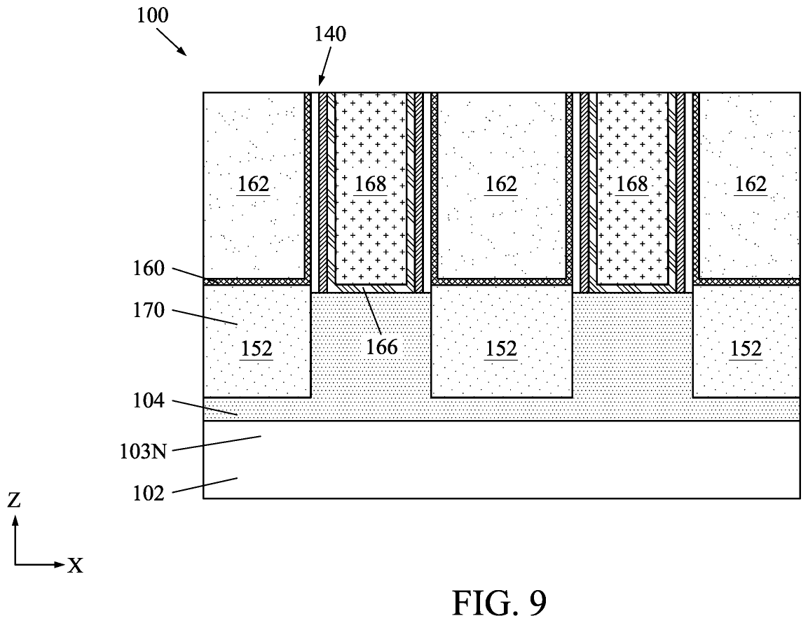

FIG. 9 is a cross-sectional side view of one of various stages of manufacturing the semiconductor device structure 100, in accordance with some embodiments. In FIG. 9, the sacrificial gate electrode layers 132 (FIG. 8) and the sacrificial gate dielectric layers 130 (FIG. 8) may be removed and replaced with gate dielectric layers 166 and gate electrode layers 168. The sacrificial gate electrode layers 132 and the sacrificial gate dielectric layers 130 may be removed by one or more etch processes, such as dry etch process, wet etch process, or a combination thereof. The one or more etch processes selectively remove the sacrificial gate electrode layers 132 and the sacrificial gate dielectric layers 130 without substantially affects the ILD layer 162. The gate dielectric layer 166 may include one or more dielectric layers and may include the same material(s) as the sacrificial gate dielectric layer 130. In some embodiments, the gate dielectric layers 166 may be deposited by one or more ALD processes or other suitable processes. The gate electrode layer 168 includes one or more layers of electrically conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layers 168 may be formed by PVD, CVD, ALD, electro-plating, or other suitable method. The gate electrode layers 168 may be recessed to a level below the top surface of the ILD layer 162, and a self-aligned contact (SAC) layer (not shown) may be formed on each gate electrode layer 168.

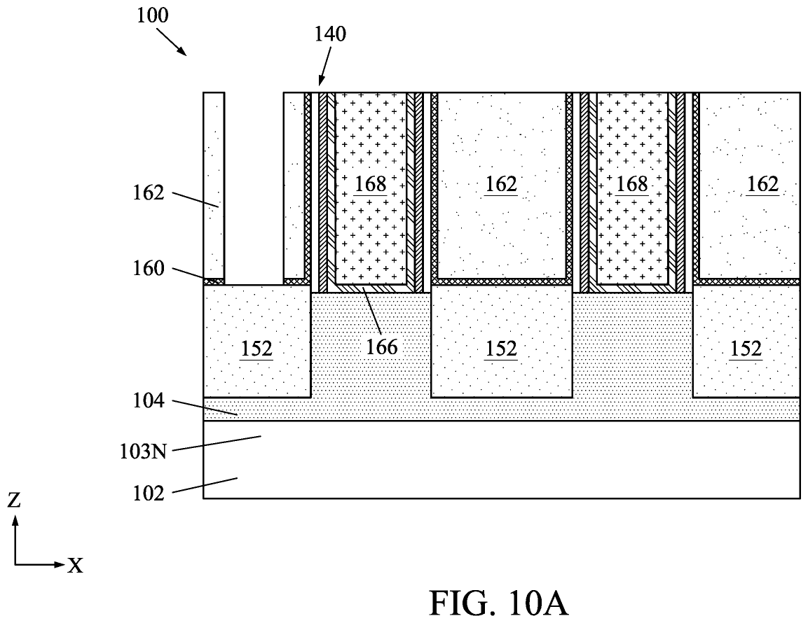

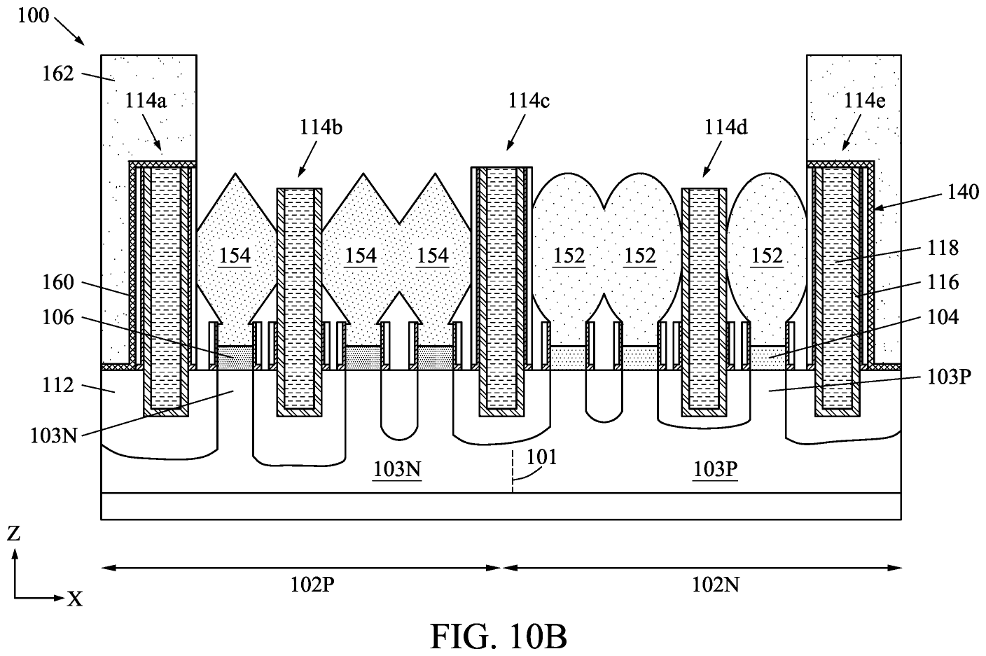

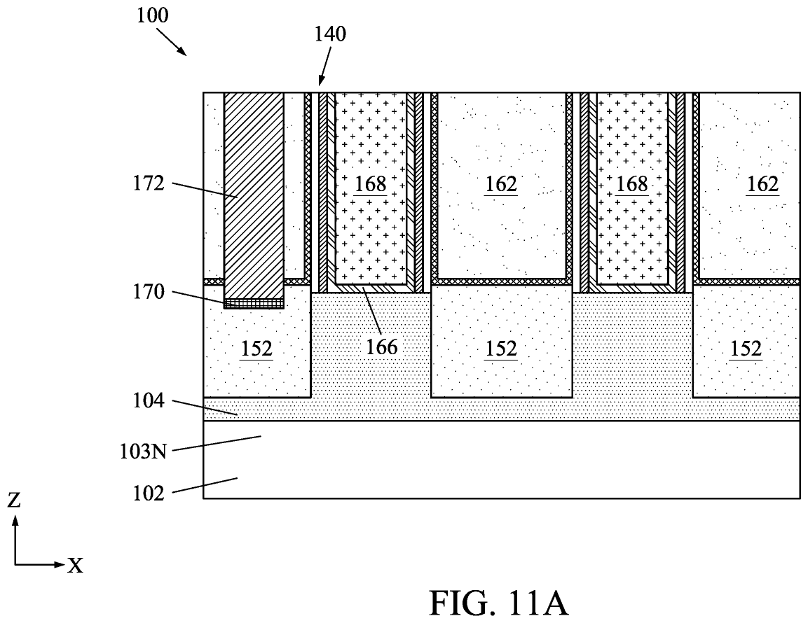

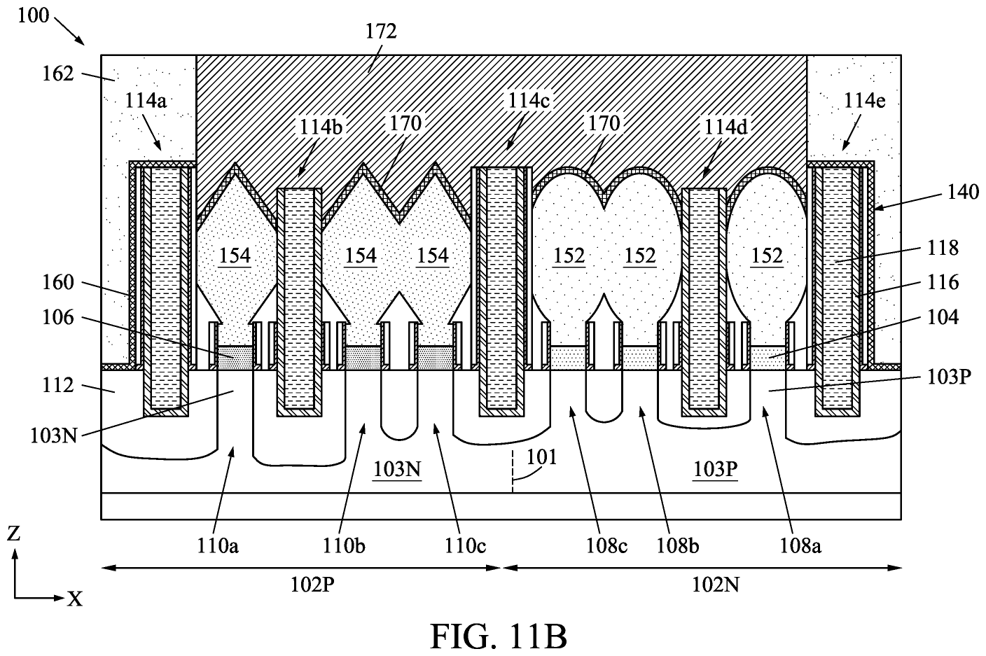

FIGS. 10A-11A and 10B-11B are cross-sectional side views of one of various stages of manufacturing the semiconductor device structures of FIG. 9, in accordance with some embodiments. In FIGS. 10A and 10B, the ILD layer 162 and the CESL 160 disposed on one side of one gate electrode layer 168 are removed, exposing the S/D epitaxial features 152, 154 and the dielectric features 114b-d. The dielectric features 114a, 114e may be still covered by the ILD layer 162. In some embodiments, the ILD layer 162 and the CESL 160 disposed on both sides of the gate electrode layers 168 are removed.

In FIGS. 11A and 11B, the conductive feature 172 is formed over the S/D epitaxial features 152, 154 and the dielectric features 114a-e. The conductive feature 172 may include an electrically conductive material, such as one or more of Ru, Mo, Co, Ni. W, Ti, Ta, Cu, Al, TiN and TaN. The conductive feature 172 may be formed by any suitable process, such as PVD, CVD, ALD, electro-plating, or other suitable method. The conductive feature 172 may include a continuous material disposed over the S/D epitaxial features 152, 154 and the dielectric features 114a-e. A silicide layer 170 may be formed between each S/D epitaxial feature 152, 154 and the conductive feature 172, as shown in FIGS. 11A and 11B. The silicide layer 170 may be also formed between each dielectric feature 114b, 114c, 114d and the conductive feature 172. The silicide layer 170 may include one or more of WSi, CoSi, NiSi, TiSi, MoSi or TaSi. In some embodiments, the portions of the silicide layer 170 disposed between the S/D epitaxial features 152, 154 and the conductive feature 172 may have the same or a different composition compared to the portions of the silicide layer 170 disposed between the dielectric features 114b, 114c, 114d and the conductive feature 172. In some embodiments, the portion of the silicide layer 170 formed between the dielectric features 114b, 114c, 114d and the conductive feature 172 has a thickness less than a thickness of the portion of the silicide layer 170 formed between the S/D epitaxial features 152, 154 and the conductive feature 172.

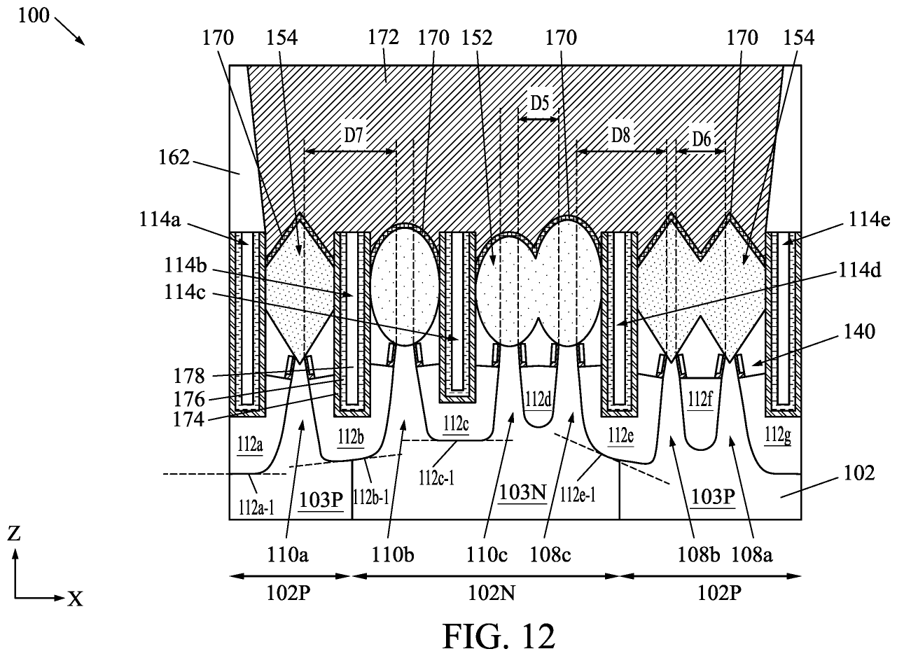

FIGS. 12-14 are cross-sectional side views of a stage of manufacturing the semiconductor device structure 100, in accordance with some embodiments. The semiconductor device structure 100 shown in FIGS. 12-14 may be alternative embodiments of the semiconductor device structure 100 shown in FIG. 11B. In some embodiments, the semiconductor device structure 100 includes structures of FIGS. 12-14 in various regions of the substrate 102.

In FIG. 12, each dielectric feature 114a-e includes a first dielectric material 174, a second dielectric material 176, and a third dielectric material 178. In some embodiments, the first, second, and third dielectric materials 174, 176, 178 include silicon nitride with different amounts of nitrogen content. For example, the first dielectric material 174 includes a first atomic percentage of nitrogen, the second dielectric material 176 includes a second atomic percentage of nitrogen greater than the first atomic percentage of nitrogen, and the third dielectric material 178 includes a third atomic percentage of nitrogen greater than the second atomic percentage of nitrogen. In some embodiments, the fin 110c and the fin 108c are separated from each other by a distance D5, the fin 108a and the fin 108b are separated from each other by a distance D6 that is substantially similar to the distance D5. The fin 110a and the fin 110b are separated from each other by a distance D7, and the fin 108b and the fin 108c are separated from each other by a distance D8 that is substantially similar to the distance D7. In some embodiments, the distance D5 and D6 are smaller than the distance D7 and D8.

In some embodiments, the dielectric feature 114a has a portion embedded in the STI 112a, the dielectric feature 114b has a portion embedded in the STI 112b, the dielectric feature 114c has a portion embedded in the STI 112c, the dielectric feature 114d has a portion embedded in the STI 112d, the dielectric feature 114e has a portion embedded in the STI 112e, the dielectric feature 114f has a portion embedded in the STI 112f, and the dielectric feature 114g has a portion embedded in the STI 112g. In some embodiments, the bottom of the dielectric feature 114c is at an elevation higher than an elevation of the bottom of the dielectric feature 114b, and the bottom of the dielectric feature 114d is at an elevation lower than the elevation of the dielectric feature 114b. The fin 110a is disposed between the STI 112a and the STI 112b, the fin 110b is disposed between the STI 112b and the STI 112c, the fin 110c is disposed between the STI 112c and the STI 112d, the fin 108c is disposed between the STI 112d and the STI 112e, the fin 108b is disposed between the STI 112e and the STI 112f, and the fin 108a is disposed between the STI 112f and the STI 112g. In some embodiments, the fins 108a, 108b are in the PMOS region 102P, the fins 108c, 110c, 110b are in the NMOS region 102N, and the fin 110a is in the PMOS region 102P. The STI 112b extends across the N-well region 103N and the P-well region 103P, and the STI 112e extends across the N-well region 103N and the P-well region 103P. In some embodiments, the two fins 110c, 108c with the merged S/D epitaxial features 152 in the NMOS region 102N, the single fin 110b with the S/D epitaxial feature 152 in the NMOS region 102N, and the single fin 110a with the S/D epitaxial feature 154 in the PMOS region 102P are part of an RO device.

In some embodiments, the S/D epitaxial features 152, 154 are in electrical contact with one single conductive feature 172 through the silicide layer 170. In some embodiments, the merged S/D epitaxial feature 152 above the fins 108c, 110c are in electrical contact with a first conductive feature through the silicide layer 170, the S/D epitaxial feature 152 above the fin 110b is in electrical contact with a second conductive feature through the silicide layer 170, and the second conductive feature is electrically separated from the first conductive feature, and the S/D epitaxial feature 154 above the fin 110a is in electrical contact with a third conductive feature through the silicide layer 170, and the third conductive feature is electrically separated from the second conductive feature, and the fins 108c and 110a-c are part of an RO device.

In some embodiments, the STI 112d has a bottom disposed at a first elevation, the STI 112c has a bottom disposed at a second elevation lower than the first elevation, the STI 112f has a bottom disposed at a third elevation lower than the second elevation, the STI 112b and the STI 112e each has a bottom disposed at a fourth elevation lower than the third elevation, and the STI 112a and the STI 112g each has a bottom disposed at a fifth elevation lower than the fourth elevation. In some embodiments, the STI 112b has a sloped bottom surface 112b-1, which is slanted from the fin 110b towards the fin 110a at a downward angle. The STI 112a and the STI 112c each has a flat bottom surface 112a-1, 112c-1 with no slope (i.e., non-inclined bottom surface). The STI 112e has a sloped bottom surface 112e-1, which is slanted from the fin 108c towards the fin 108b at a downward angle. In some embodiments, the fins 110a, 108a, 108b in the PMOS region 102P extend deeper into the substrate 102 than the fins 110b, 110c, and 108c in the NMOS region 102N. The different depths of the fins 108a-c and 110a-c may be formed during the process described in FIG. 1C.

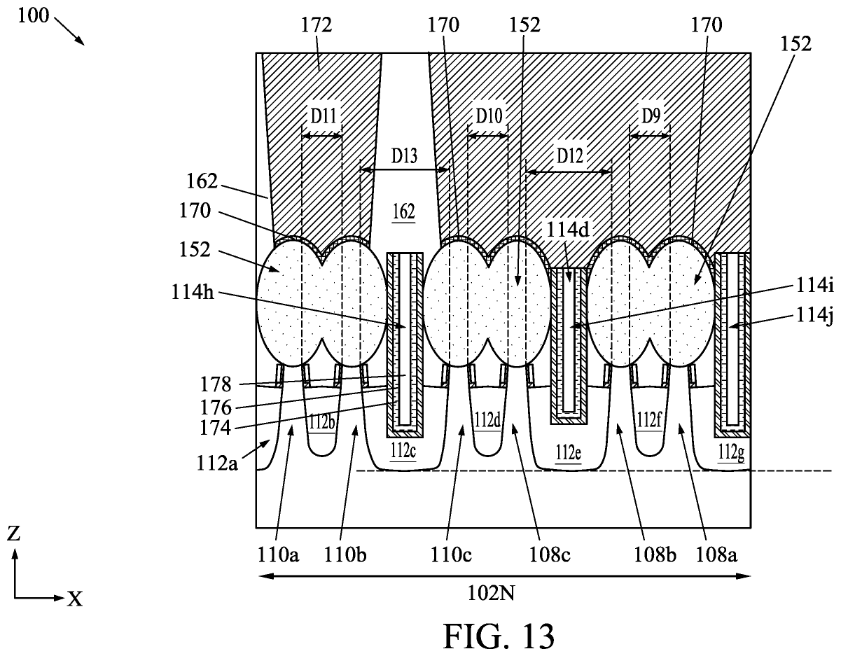

In FIG. 13, each dielectric feature 114h, 114i, 114j includes a first dielectric material 174, a second dielectric material 176, and a third dielectric material 178. In some embodiments, the first, second, and third dielectric materials 174, 176, 178 include silicon nitride with different amounts of nitrogen content. For example, the first dielectric material 174 includes a first atomic percentage of nitrogen, the second dielectric material 176 includes a second atomic percentage of nitrogen greater than the first atomic percentage of nitrogen, and the third dielectric material 178 includes a third atomic percentage of nitrogen greater than the second atomic percentage of nitrogen. In some embodiments, the fin 108a and the fin 108b are separated from each other by a distance D9, the fin 108c and the fin 108b are separated from each other by a distance D10, and the fin 110a and the fin 110b are separated from each other by a distance D11, wherein the distance D9, D10, D11 are substantially the same. The fin 108b and the fin 108c are separated from each other by a distance D12, and the fin 110b the fin 110c are separated from each other by a distance D13 that is substantially similar to the distance D12. In some embodiments, the distance D9, D10, D11 are smaller than the distance D12 and D13.

In some embodiments, the dielectric feature 114h has a portion embedded in the STI 112c, the dielectric feature 114i has a portion embedded in the STI 112e, and the dielectric feature 114j has a portion embedded in the STI 112g. In some embodiments, the dielectric feature 114i have a height shorter than the height of the dielectric features 114h and 114j. Such a difference in height may be achieved during the removal of the first and/or second semiconductor layers 104, 106 for S/D epitaxial features 152 and/or the formation of contact openings for the S/D epitaxial features 152. In one embodiment, the dielectric feature 114i has a height that is about 15 percent to about 30 percent shorter than the height of the dielectric features 114h, 114j. The fin 108a and the fin 108b are disposed between the STI 112e and the STI 112g, the fin 108c and the fin 110c are disposed between the STI 112c and the STI 112e, and the fin 110a and the fin 110b are disposed between the STI 112a and the STI 112c. In some embodiments, the merged S/D epitaxial features 152 above the fins 108a, 108b, the merged S/D epitaxial features 152 above the fins 108c, 110c, and the merged S/D epitaxial features 152 above the fins 110a, 110b are in the NMOS region 102N and serve as S/D contacts.

In some embodiments, the merged S/D epitaxial features 152 above the fins 108a-c and 110a-c are in electrical contact with one single conductive feature 172 through the silicide layer 170. Alternatively, the merged S/D epitaxial features 152 above the fins 108c, 110c and the merged S/D epitaxial features 152 above the fins 108a, 108b are in electrical contact with a first conductive feature through the silicide layer 170, and the merged S/D epitaxial feature 152 above the fins 110a, 110b are in electrical contact with a second conductive feature through the silicide layer 170, and the second conductive feature is electrically separated from the first conductive feature.

In some embodiments, the STI 112c has a bottom disposed at a first elevation, the STI 112e has a bottom disposed at a second elevation, and the STI 112g has a bottom disposed at a third elevation, wherein the first, second, and third elevation are substantially the same. In some embodiments, the bottoms of the STI 112c, 112e, 112g are flat and non-inclined surfaces.

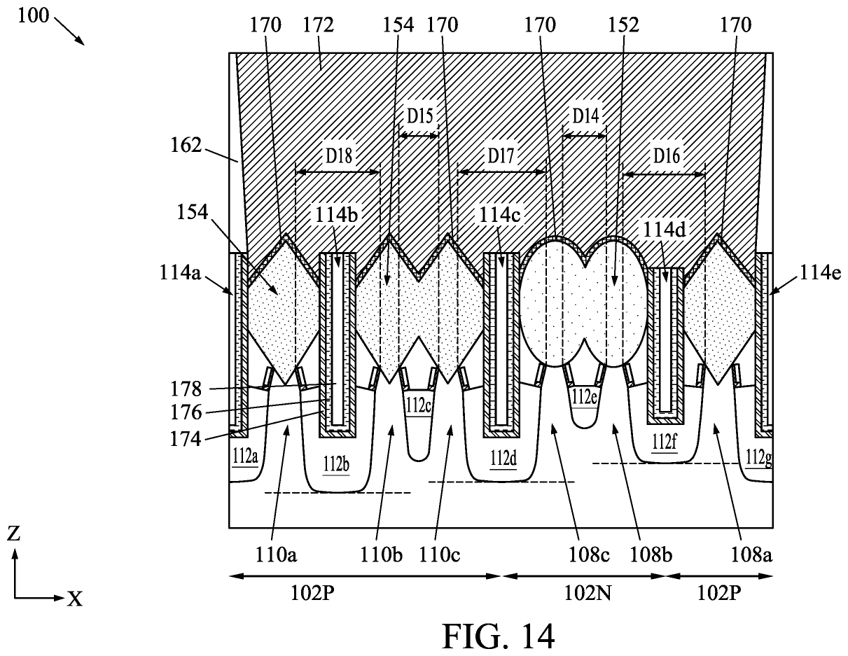

In FIG. 14, each dielectric feature 114a-e includes a first dielectric material 174, a second dielectric material 176, and a third dielectric material 178. In some embodiments, the first, second, and third dielectric materials 174, 176, 178 include silicon nitride with different amounts of nitrogen content. For example, the first dielectric material 174 includes a first atomic percentage of nitrogen, the second dielectric material 176 includes a second atomic percentage of nitrogen greater than the first atomic percentage of nitrogen, and the third dielectric material 178 includes a third atomic percentage of nitrogen greater than the second atomic percentage of nitrogen. In some embodiments, the fin 108b and the fin 108c are separated from each other by a distance D14, and the fin 110b and the fin 110c are separated from each other by a distance D15, wherein the distance D14 and D15 are substantially the same. The fin 108a and the fin 108b are separated from each other by a distance D16, the fin 108c the fin 110c are separated from each other by a distance D17, and the fin 110a and the fin 110b are separated from each other by a distance D18, wherein the distance D16, D17, and D18 are substantially the same. In some embodiments, the distance D14 and D15 are smaller than the distance D16, D17, and D18.

In some embodiments, the dielectric feature 114b has a portion embedded in the STI 112b, the dielectric feature 114c has a portion embedded in the STI 112d, and the dielectric feature 114d has a portion embedded in the STI 112f. In some embodiments, the dielectric feature 114d have a height shorter than the height of the dielectric features 114b and 114c. Such a difference in height may be achieved during the removal of the first and/or second semiconductor layers 104, 106 for S/D epitaxial features 152, 154, and/or the formation of contact openings for the S/D epitaxial features 152, 154. In one embodiment, the dielectric feature 114d has a height that is about 15 percent to about 30 percent shorter than the height of the dielectric features 114b, 114c. The fin 108b and the fin 108c are disposed between the STI 112d and the STI 112f, the fin 110b and the fin 110c are disposed between the STI 112b and the STI 112d, the fin 110a is disposed between the STI 112a and the STI 112b, and the fin 108a is disposed between the STI 112f and the STI 112g. In some embodiments, the merged S/D epitaxial features 152 above the fins 108b, 108c are in the NMOS region 102N, the merged S/D epitaxial features 154 above the fins 110b, 110c are in the PMOS region 102P, the S/D epitaxial feature 154 above the single fin 110a is in the PMOS region 102P, and the S/D epitaxial feature 154 above the single fin 108a is in the PMOS region 102P, wherein the merged S/D epitaxial features 152, 154 above the fins 108a-c and 110a-c are in electrical contact with one single conductive feature 172. In one embodiment, the conductive feature 172 is an extended metal plug serving as a S/D contact for connecting with a power rail. In such cases, the merged S/D epitaxial features 152, 154 above the fins 108a-c and 110a-c are in electrical contact with one single conductive feature 172 through the silicide layer 170.

In some embodiments, the STI 112b has a bottom disposed at a first elevation, the STI 112d has a bottom disposed at a second elevation higher than the first elevation, the STI 112f has a bottom disposed at a third elevation higher than the second elevation. In some embodiments, the bottoms of the STI 112b, 112d, 112f are flat and non-inclined surfaces. In some embodiments, one or more bottoms of the STI 112b, 112d, 112f have a slope. For example, the bottom of the STI 112d may be slanted towards the fin 110c at a downward angle, and the bottom of the STI 112f may be slanted towards the fin 108a at a downward angle. The STI 112b may have a flat bottom with no slope (i.e., non-inclined surface).

While various embodiments of FIGS. 1A-14 are described with respect to FinFETs, implementations of some aspects of the present disclosure may be used in other processes and/or in other devices, such as nanosheet (or nanostructure) FETs, planar FETs, Horizontal Gate All Around (HGAA) FETs, Vertical Gate All Around (VGAA) FETs, and other suitable devices. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

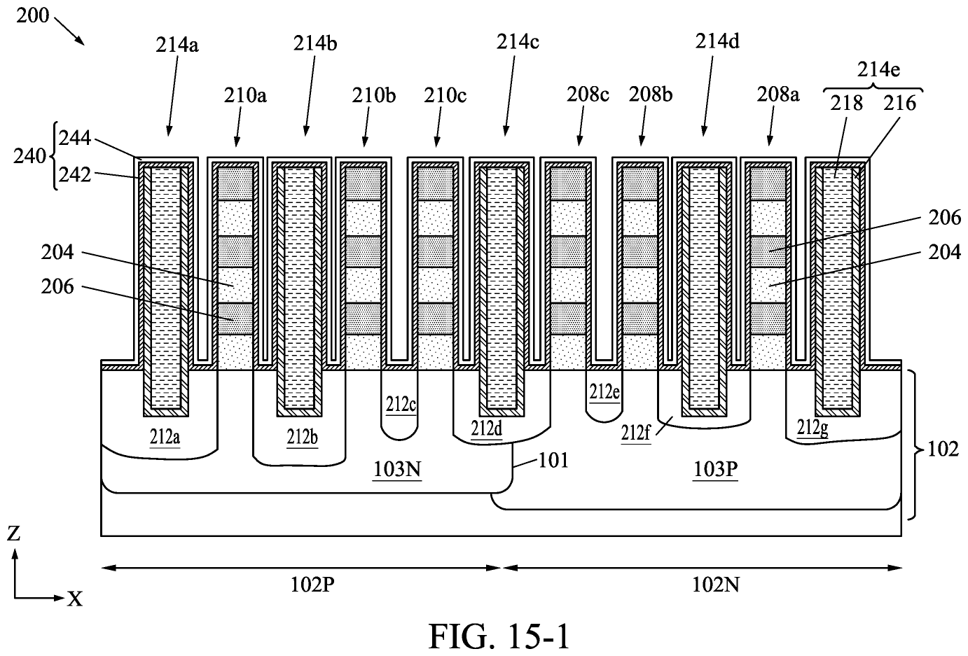

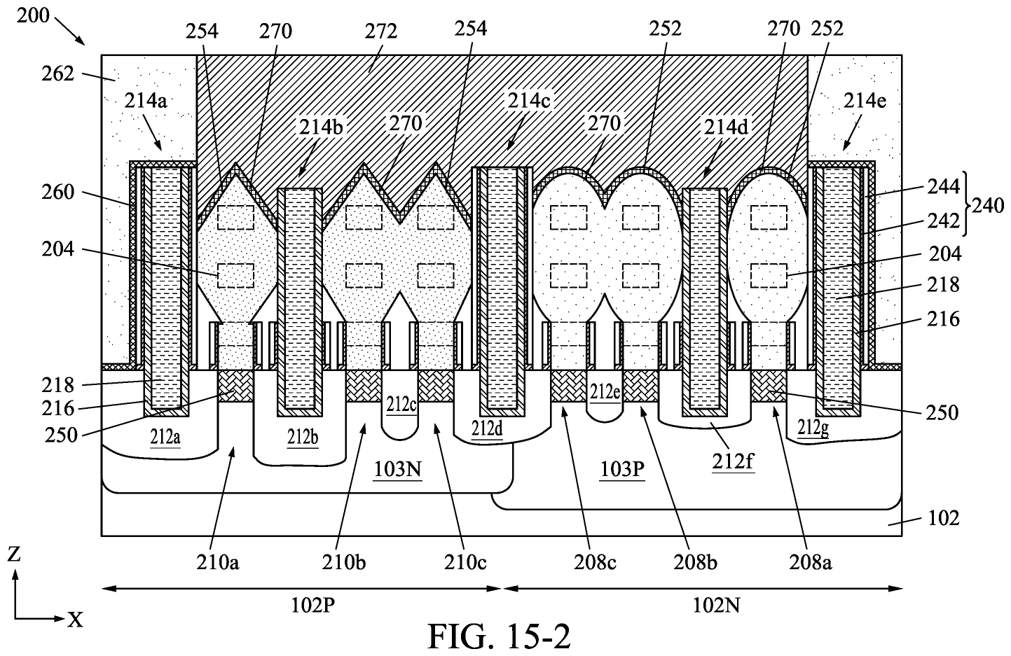

FIG. 15-1 is a cross-sectional side view of a stage of manufacturing the semiconductor device structure 200, in accordance with some embodiments. The embodiment in FIG. 15-1 can be used for forming a GAA-based transistor structure. FIG. 15-2 is a cross-sectional side view of the semiconductor device structure 200 showing the plane cutting along the source/drain region and perpendicular to the direction of the fins. In FIG. 15-1, a stack of semiconductor layers is formed on a substrate, such as the substrate 102. The stack of semiconductor layers may include any numbers of first and second semiconductor layers 204, 206, such as the first and second semiconductor layers 104, 106. In one embodiment, three first semiconductor layers 204 and three second semiconductor layers 206 are alternately arranged in the stack of semiconductor layers. Once the stack of semiconductor layers is formed, the fins 208a-c, 210a-c are fabricated from the stack of semiconductor layers and a portion of the substrate, and insulating material, such as the insulating material 112, is formed and recessed to form shallow trench isolation (STI) 212a-g around respective fin. The fins 208a-c, 210a-c and the STI 212a-g may be formed using any suitable processes, such as the processes described in FIGS. 1C-1F above. In some embodiments, optional dielectric features 214a-e, such as dielectric features 114a-e, are selectively formed between adjacent fins. Each dielectric feature 114a-e includes a liner 216 and a low-K dielectric material 218, such as the liner 116 and the low-K dielectric material 118. The dielectric feature 214a is disposed adjacent the fin 210a, the dielectric feature 214b is disposed between the fin 210a and the fin 210b, the dielectric feature 214c is disposed between the fin 210c and the fin 208c, the dielectric 214d is disposed between the fin 208a and the fin 208b, and the dielectric feature 214e is disposed adjacent the fin 208a.

Next, sacrificial gate stacks (not shown) are formed over portions of the fins. The sacrificial gate stacks each incudes a sacrificial gate electrode layer and a mask structure. A spacer 240, such as the spacer 140, is formed on sidewalls of the sacrificial gate stack. The spacer 240 may include a first layer 242, such as the first layer 142, and a second layer 244, such as the second layer 144. The spacer 240 and the sacrificial gate electrode layer may be formed using any suitable processes, such as the processes described in FIGS. 2A-2B to 3A-3B. The exposed portions of the fins not covered by the sacrificial gate stacks are recessed. Edge portions of the stacks of semiconductor layers under the sacrificial gate stacks and the spacers are slightly horizontally etched. Particularly, the edge portions of each second semiconductor layer 206 are removed and replaced with a dielectric spacer.

Then, in FIG. 15-2, source/drain (S/D) epitaxial features 252, 254, such as the S/D epitaxial features 152, 154, are formed on the substrate portions. In some embodiments, the exposed portions of the fins are not recessed, and the S/D epitaxial features 252, 254 are grown directly from the exposed portions of the fins, as shown in FIG. 15. The S/D epitaxial features 252, 254 may be formed by any suitable processes, such as the processes described in FIGS. 4A-4B to 5A-5B. In some embodiments, the S/D epitaxial features 252, 254 may include an undoped semiconductor material 250, such as Si, SiP, SiC, SiAs, SiCP SiGe, or Ge. The undoped semiconductor material 250 serves as a buffer layer for better growth control of the S/D epitaxial features 252, 254.

Thereafter, the sacrificial gate stacks are removed, forming openings to expose the first semiconductor layers 204 (represented by dotted lines) disposed under the sacrificial gate stacks. The exposed first semiconductor layers serve as channel regions for the semiconductor device structure 200. Gate dielectric layers (not shown), gate electrode layers (not shown), and self-aligned contact (SAC) layers (not shown) are sequentially formed in the openings to form replacement gate stacks (not shown). The gate electrode layer wraps around the exposed first semiconductor layers 204. CESL layer 260 and ILD layer 262, such as the CESL layer 160 and the ILD layer 162, are sequentially formed on the S/D epitaxial features 252, 254 and the replacement gate stacks. Portions of the ILD layer 262 and CESL layer 260 are then removed to expose the S/D epitaxial features 252, 254. A silicide layer 270, such as the silicide layer 170, is formed on the exposed S/D epitaxial features 252, 254 and exposed surfaces of the dielectric features (if present). A conductive feature 272, such as the conductive feature 172, is formed on the silicide layer, resulting in the semiconductor device structure 200 shown in FIG. 15-2. The semiconductor device structure 200, particularly the profile of the STI 212a-212g, is substantially similar to the semiconductor device structure 100 shown in FIG. 11B. Details of the profile of the STI 212a-g may refer to those discussed above with respect to FIGS. 1C-1F.

The present disclosure provides a semiconductor device structure having different profiles of shallow trench isolations (STI) and respective S/D epitaxial features for NMOS and PMOS devices. Each S/D epitaxial feature is formed over a respective fin that includes a substrate portion and a N-well or P-well portion. The N-well and P-well portions include anti-punch through (APT) dopants. The STI are formed with bottoms at different slopes and heights in N-well and/or P-well regions of the substrate so that the APT dopants in the N-well or P-well portion of fins can extend different depths within the STI to help reduce or prevent the short channel effect of electrons or holes punching through from the source to the drain. As a result, isolation leakage is controlled and the device performance is improved.

An embodiment is a semiconductor device structure. The semiconductor device structure includes a substrate comprising an NMOS region and a PMOS region abutting the NMOS region, a first shallow trench isolation (STI) disposed across the PMOS region and the NMOS region, the first STI has a first bottom being slanted from the NMOS region towards the PMOS region. The semiconductor device structure also includes a first fin disposed in the PMOS region, a first source/drain epitaxial feature disposed over the first fin, a second fin disposed in the NMOS region, a second source/drain epitaxial feature disposed over the second fin, a first dielectric feature disposed between the first source/drain epitaxial feature and the second source/drain epitaxial feature, the first dielectric feature having a portion embedded in the first STI. The semiconductor device structure further includes a conductive feature disposed over the first and second source/drain epitaxial features and the first dielectric feature.

Another embodiment is a semiconductor device structure. The semiconductor device structure includes a substrate comprising a first P-well region, a second P-well region, and an N-well region disposed between the first and second P-well regions, a first shallow trench isolation (STI) disposed in the N-well region, the first STI having a non-inclined bottom surface, a second STI disposed in the N-well region, a third STI disposed across the N-well region and the first P-well region, the third STI having a sloped bottom surface with respect to the non-inclined bottom surface of the first STI, and a fourth STI disposed across the N-well region and the second P-well region, the fourth STI having a sloped bottom surface with respect to the non-inclined bottom surface of the first STI.

A further embodiment is a method. The method includes forming first and second semiconductor fins in a PMOS region by a first etch process, wherein a first trench between the first and second semiconductor fins is etched to have a first bottom at a first elevation. The method also includes forming third and fourth semiconductor fins in a NMOS region by the first etch process, wherein a second trench between the third and fourth semiconductor fins is etched to have a second bottom at a second elevation higher than the first elevation, and a third trench between the second and third semiconductor fins is etched to have a third bottom at a third elevation lower than the first elevation. The method also includes filling the first, second, and third trenches with an insulating material, forming first, second, and third dielectric features in the insulating material within the first, second, and third trenches, wherein the first and second semiconductor fins are disposed between the first and second dielectric features, and the third and fourth semiconductor fins are disposed between the second and third dielectric features. The method also includes recessing the insulating material by a second etch process to form: a first shallow trench isolation (STI) around the first dielectric feature, the first STI having a first thickness, a second STI between the first and second semiconductor fins, the second STI having a second thickness shorter the first thickness, a third STI around the second dielectric feature, the third STI having a third thickness greater than the second thickness, a fourth STI between the third and fourth semiconductor fins, the fourth STI having a fourth thickness shorter than the second thickness, and a fifth STI around the third dielectric feature, the fifth STI having a fifth thickness between the second and fourth thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a substrate comprising an NMOS region and a PMOS region abutting the NMOS region;
a first shallow trench isolation (STI) disposed across the PMOS region and the NMOS region, the first STI has a first bottom being slanted from the NMOS region towards the PMOS region;
a first fin disposed in the PMOS region;
a first source/drain epitaxial feature disposed over the first fin;
a second fin disposed in the NMOS region;
a second source/drain epitaxial feature disposed over the second fin;
a first dielectric feature disposed between the first source/drain epitaxial feature and the second source/drain epitaxial feature, the first dielectric feature having a portion embedded in the first STI; and
a conductive feature disposed over the first and second source/drain epitaxial features and the first dielectric feature.

2. The semiconductor device structure of claim 1, further comprising:
a third fin disposed adjacent the first fin;
a third source/drain epitaxial feature disposed over the third fin, a portion of the third source/drain epitaxial feature being merged with a portion of the first source/drain epitaxial feature;
a fourth fin disposed adjacent the second fin; and
a fourth source/drain epitaxial feature disposed over the fourth fin, a portion of the fourth source/drain epitaxial feature being merged with a portion of the second source/drain epitaxial feature.

3. The semiconductor device structure of claim 2, further comprising:
a second STI disposed between second fin and the fourth fin, the second STI having a second bottom at an elevation higher than an elevation of the first bottom of the first STI.

4. The semiconductor device structure of claim 3, further comprising:
a third STI disposed between first fin and the third fin, the third STI having a third bottom at an elevation higher than the elevation of the second bottom of the second STI.

5. The semiconductor device structure of claim 4, further comprising:
a fourth STI disposed adjacent the fourth fin, the fourth STI having a fourth bottom at an elevation lower than the first bottom of the first STI; and
a second dielectric feature having a portion embedded in the fourth STI.

6. The semiconductor device structure of claim 5, further comprising:
a fifth STI disposed adjacent the third fin, the fifth STI having a fifth bottom at an elevation between the elevation of the first bottom of the first STI and the elevation of the third bottom of the third STI; and
a third dielectric feature having a portion embedded in the fifth STI.

7. The semiconductor device structure of claim 6, wherein the second and third dielectric features have a height shorter than a height of the first dielectric feature.

8. The semiconductor device structure of claim 6, wherein the first, second and third dielectric features have a bottom at the same elevation.

9. The semiconductor device structure of claim X, further comprising a silicide layer disposed between the first source/drain epitaxial feature and the conductive feature and between the second source/drain epitaxial feature and the conductive feature.

10. The semiconductor device structure of claim 9, wherein the first dielectric feature comprises a liner and a low-K dielectric material disposed on the liner, and the low-K dielectric material is in contact with the conductive feature, the silicide layer, the first source/drain epitaxial feature, and the second source/drain epitaxial feature.

11. A semiconductor device structure, comprising:
a substrate comprising a first P-well region, a second P-well region, and an N-well region disposed between the first and second P-well regions;
a first shallow trench isolation (STI) disposed in the N-well region, the first STI having a non-inclined bottom surface;
a second STI disposed in the N-well region;
a third STI disposed across the N-well region and the first P-well region, the third STI having a sloped bottom surface with respect to the non-inclined bottom surface of the first STI; and
a fourth STI disposed across the N-well region and the second P-well region, the fourth STI having a sloped bottom surface with respect to the non-inclined bottom surface of the first STI.

12. The semiconductor device structure of claim 11, wherein the sloped bottom surface of the third STI is slanted from the N-well region towards the first P-well region at a downward angle.

13. The semiconductor device structure of claim 12, wherein the sloped bottom surface of the fourth STI is slanted from the N-well region towards the second P-well region at a downward angle.

14. The semiconductor device structure of claim 13, wherein the non-inclined bottom surface is at an elevation higher than an elevation of the slopped bottom surfaces of the third STI and the fourth STI.

15. The semiconductor device structure of claim 11, further comprising:
a first source/drain epitaxial feature disposed over the N-well region between the first STI and the second STI;
a second source/drain epitaxial feature disposed over the N-well region between the second STI and the third STI,
wherein the first and second source/drain epitaxial features are partially merged.

16. The semiconductor device structure of claim 15, further comprising:
a third source/drain epitaxial feature disposed over the N-well region between the first STI and the fourth STI; and
a first dielectric feature disposed between the first source/drain epitaxial feature and the third source/drain epitaxial feature, the first dielectric feature having a portion embedded in the first STI.

17. The semiconductor device structure of claim 16, further comprising:
a second dielectric feature disposed adjacent the third source/drain epitaxial feature and away from the first dielectric feature, the second dielectric feature having a portion embedded in the fourth STI, and a bottom of the portion of the second dielectric feature is at an elevation lower than a bottom of the portion of the first dielectric feature.

18. A method for forming a semiconductor device structure, comprising:
forming first and second semiconductor fins in a PMOS region by a first etch process, wherein a first trench between the first and second semiconductor fins is etched to have a first bottom at a first elevation;
forming third and fourth semiconductor fins in a NMOS region by the first etch process, wherein a second trench between the third and fourth semiconductor fins is etched to have a second bottom at a second elevation higher than the first elevation, and a third trench between the second and third semiconductor fins is etched to have a third bottom at a third elevation lower than the first elevation;
filling the first, second, and third trenches with an insulating material;
forming first, second, and third dielectric features in the insulating material within the first, second, and third trenches, wherein the first and second semiconductor fins are disposed between the first and second dielectric features, and the third and fourth semiconductor fins are disposed between the second and third dielectric features; and
recessing the insulating material by a second etch process to form:
a first shallow trench isolation (STI) around the first dielectric feature, the first STI having a first thickness;
a second STI between the first and second semiconductor fins, the second STI having a second thickness shorter the first thickness;
a third STI around the second dielectric feature, the third STI having a third thickness greater than the second thickness;
a fourth STI between the third and fourth semiconductor fins, the fourth STI having a fourth thickness shorter than the second thickness; and
a fifth STI around the third dielectric feature, the fifth STI having a fifth thickness between the second and fourth thickness.

19. The method of claim 18, further comprising:
recessing the third and fourth semiconductor fins by a third etch process;
forming a first source/drain epitaxial feature over the recessed third and fourth semiconductor fins;
recessing the first and second semiconductor fins by a fourth etch process;
forming a second source/drain epitaxial feature over the recessed first and second semiconductor fins; and
forming a conductive feature over the first and second source/drain epitaxial features and the first, second, and third dielectric features.

20. The method of claim 18, wherein the third STI has a bottom being slanted from the NMOS region towards the PMOS region at a downward angle.
